(19) United States
(12) Patent Application Publication
(10) Pub. No.: US 2025/0357225 A1
(43) Pub. Date: Nov. 20, 2025

(54) ELECTRONIC MODULE, ELECTRONIC APPARATUS, AND ELECTRONIC MODULE MANUFACTURING METHOD

(71) Applicant: FUJI ELECTRIC CO., LTD., Kawasaki-shi, (JP)

(72) Inventor: Hitoshi NAKATA, Matsumoto-city, (JP)

(73) Assignee: FUJI ELECTRIC CO., LTD., Kawasaki-shi, Kanagawa (JP)

(21) Appl. No.: 19/282,946

(22) Filed: Jul. 28, 2025

Related U.S. Application Data
(63) Continuation of application No. PCT/JP2024/024211, filed on Jul. 4, 2024.

(30) Foreign Application Priority Data
Aug. 22, 2023 (JP) 2023-134687

(51) Int. Cl. H01L 23/047; H01L 21/48; H01L 23/00; H01L 23/31; H01L 23/373; H01L 25/07; H10D 80/20

(52) U.S. Cl. CPC H01L 23/047; H01L 21/4817; H01L 23/3121; H01L 23/3735; H01L 24/40; H01L 25/072; H10D 80/215; H10D 80/251; H01L 2224/40225; H01L 2924/10253; H01L 2924/10272; H01L 2924/1205; H01L 2924/13055; H01L 2924/13091; H01L 2924/3511; H01L 2924/3512

(57) ABSTRACT

An electronic module, including: a first conductive plate which contains copper or a first copper alloy as a main component thereof; a second conductive plate which has a main surface that faces the first conductive plate and has a side surface that extends continuously from the main surface, and which contains copper or a second copper alloy as a main component thereof; and a first metal oxide layer which is provided on the main surface and the side surface of the second conductive plate, and which contains a first metal oxide that is of a metal different from a metal of the second conductive plate and is electrically insulating.

### CROSS-REFERENCE TO RELATED APPLICATION

This application is a continuation application of International Application PCT/JP2024/024211 filed on Jul. 4, 2024, which designated the U.S., which claims priority to Japanese Patent Application No. 2023-134687, filed on Aug. 22, 2023, the entire contents of which are incorporated herein by reference.

### BACKGROUND OF THE INVENTION

### 1. Field of the Invention

The embodiments discussed herein relate to an electronic module, an electronic apparatus, and an electronic module manufacturing method.

### 2. Background of the Related Art

The semiconductor device includes a semiconductor module and a capacitor. The semiconductor module includes an N-type power terminal and a P-type power terminal disposed on the N-type power terminal with an insulating member interposed therebetween such that one end portion of the N-type power terminal is exposed. The capacitor includes an N-type connection terminal, which is connected to one end portion of the N-type power terminal, and a P-type connection terminal provided on the N-type connection terminal with an insulating member interposed therebetween. The P-type connection terminal and the P-type power terminal are connected by a coupling member (see, for example, Japanese Laid-open Patent Publication No. 2021-106235).

There are cases in which an aluminum oxide film is formed as an insulating member on a surface of a metal plate in a substrate in a power module.

The aluminum oxide film is formed by anodic oxidation (see, for example, Japanese Laid-open Patent Publication No. 2013-080924, Japanese Laid-open Patent Publication NO. 2012-099782, and Japanese Laid-open Patent Publication No. 2012-099779). In addition, there are cases in which a clad material is used as an electric circuit substrate. The clad material is formed by forming a copper layer and forming an aluminum layer on the opposite side of the copper layer by roll cladding (for example, see Bimetal Japan Inc., “Clad Material”, Internet <URL: www.bimetal.co.jp/clad.html>). Using such a clad material, an insulating layer is formed on the front surface of the aluminum layer by anodic oxidation. The insulating layer is bonded to a metal layer forming a cooling body via an adhesive layer (see, for example, Japanese National Publication of International Patent Application No. 2018-533197).

When an aqueous oxalic acid solution is used as an electrolytic solution at the time of forming an insulating layer of a semiconductor device by anodic oxidation, the dielectric breakdown voltage at a film thickness of 20 μm is about 1 kV in the case of unsealed pores and about 1.3 kV in the case of sealed pores (see, for example, Ken Asato, Takehiko Muranaka, and Masatsugu Maejima, “Withstand Voltage of Anodic Oxide Film on Aluminum Alloy”, Report of Yamaguchi Prefectural Industrial Technology Institute, No. 33, p. 12-16, 2021).

### SUMMARY OF THE INVENTION

According to an aspect of the present disclosure, there is provided an electronic module, including: a first conductive plate which contains copper or a first copper alloy as a main component thereof; a second conductive plate which has a main surface that faces the first conductive plate and has a side surface that extends continuously from the main surface, and which contains copper or a second copper alloy as a main component thereof; and a metal oxide layer which is provided on the main surface and the side surface of the second conductive plate, and which contains a metal oxide that is of a metal different from a metal of the second conductive plate and is electrically insulating.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor module according to a first embodiment;

FIG. 2 is a plan view of a semiconductor unit according to the first embodiment;

FIG. 3 is a cross-sectional view of the semiconductor unit according to the first embodiment;

FIG. 4 is a plan view of a terminal stack portion according to the first embodiment;

FIG. 5 is a plan view of a first terminal included in the terminal stack portion according to the first embodiment;

FIG. 6 is a plan view of a second terminal included in the terminal stack portion according to the first embodiment;

FIG. 7 is a cross-sectional view of the terminal stack portion according to the first embodiment;

FIG. 8 is a cross-sectional view of the terminal stack portion from which bonding areas are removed according to the first embodiment;

FIG. 9 is a flowchart illustrating a method of manufacturing a case included in the semiconductor module according to the first embodiment;

FIG. 10 is a diagram illustrating a coating step included in the case manufacturing method according to the first embodiment;

FIG. 11 is a diagram illustrating an oxidation step included in the case manufacturing method according to the first embodiment;

FIG. 12 is a flowchart illustrating a method of manufacturing a case included in a semiconductor module according to modification 1-1 according to the first embodiment;

FIGS. 13A to 13C are diagrams illustrating a preparation step included in the case manufacturing method according to modification 1-1 according to the first embodiment;

FIGS. 14A and 14B are diagrams illustrating a terminal forming step and an oxidation step included in the case manufacturing method according to modification 1-1 according to the first embodiment;

FIG. 15 is a cross-sectional view of a terminal stack portion according to modification 1-1 according to the first embodiment;

FIG. 16 is a cross-sectional view of a terminal stack portion from which bonding areas are removed according to modification 1-1 according to the first embodiment;

FIG. 17 is a perspective view of a semiconductor device according to a second embodiment;

FIGS. 18A and 18B are perspective views of a capacitor according to the second embodiment;

FIG. 19 is a cross-sectional view of the capacitor and a semiconductor module included in the semiconductor device according to the second embodiment;

FIG. 20 is a perspective view of a semiconductor module according to a third embodiment;

FIG. 21 is a cross-sectional view of the semiconductor module according to the third embodiment;

FIG. 22 is a plan view of the semiconductor module according to the third embodiment;

FIG. 23 is a plan view of a first terminal and a second terminal according to the third embodiment;

FIG. 24 is a cross-sectional view of the first terminal and the second terminal according to the third embodiment;

FIG. 25 is another cross-sectional view of the first terminal and the second terminal according to the third embodiment;

FIG. 26 is a cross-sectional view of a first terminal and a second terminal according to modification 3-1 according to the third embodiment;

FIG. 27 is a cross-sectional view of a first terminal, a second terminal, and a third terminal according to modification 3-2 according to the third embodiment;

FIG. 28 is a cross-sectional view of a first terminal, a second terminal, and a third terminal according to modification 3-3 according to the third embodiment;

FIG. 29 is a side view of a semiconductor device according to a fourth embodiment;

FIG. 30 is a plan view of the semiconductor device according to the fourth embodiment;

FIG. 31 is a cross-sectional view of a semiconductor module according to the fourth embodiment;

FIG. 32 is a plan view of a bus bar according to the fourth embodiment;

FIG. 33 is a first cross-sectional view of the bus bar according to the fourth embodiment; and

FIGS. 34A and 34B are second cross-sectional views of the bus bar according to the fourth embodiment.

### DETAILED DESCRIPTION OF THE INVENTION

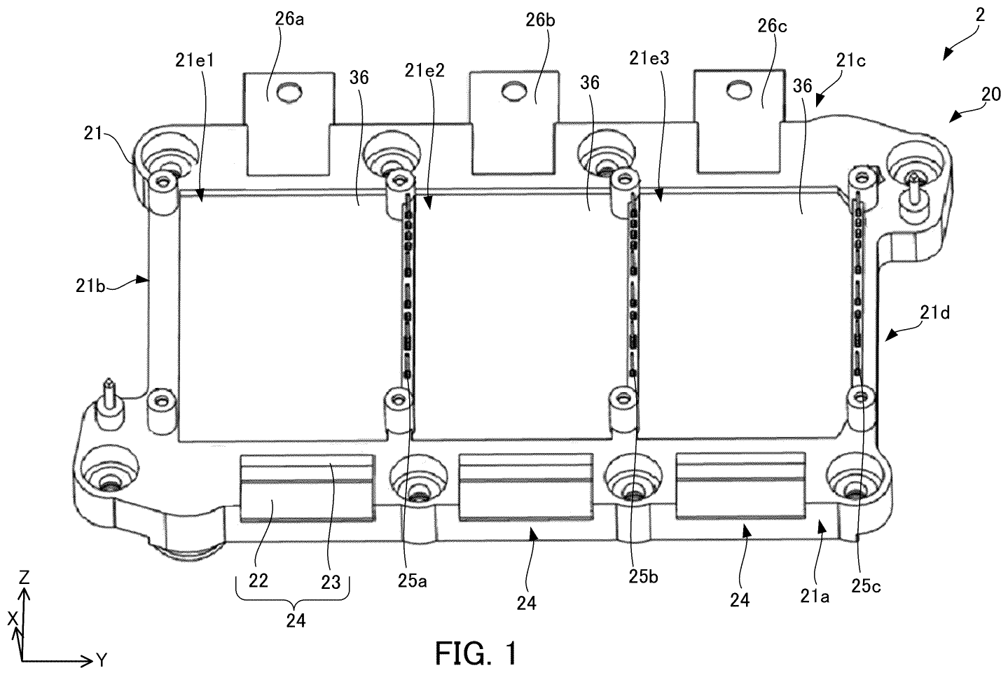

Hereinafter, embodiments will be described with reference to the accompanying drawings. In the following description, regarding a semiconductor device 1 in FIG. 1, terms “front surface” and “top surface” each express an X-Y plane facing upward (±Z direction). Likewise, regarding the semiconductor device 1 in FIG. 1, a term “up” expresses the upward direction (±Z direction). Regarding the semiconductor device 1 in FIG. 1, terms “rear surface” and “bottom surface” each express an X-Y plane facing downward (−Z direction). Likewise, regarding the semiconductor device 1 in FIG. 1, a term “down” expresses the downward direction (−Z direction). As needed, the above terms also mean their respective directions in the other drawings. Regarding the semiconductor device 1 in FIG. 1, a phase “higher level” expresses an upper location (±Z direction). Likewise, regarding the semiconductor device 1 in FIG. 1, a phase “lower level” expresses a lower location (−Z direction). The terms “front surface”, “top surface”, “up”, “rear surface”, “bottom surface”, “down”, and “side surface” are simply used as convenient expressions to determine relative positional relationships, and do not limit the technical ideas of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in a material represents 80 vol % or more of the material, this component will be referred to as “main component” of the material.

### First Embodiment

A semiconductor module included in a semiconductor device according to a first embodiment will be described with reference to FIG. 1. FIG. 1 is a plan view of a semiconductor module according to a first embodiment.

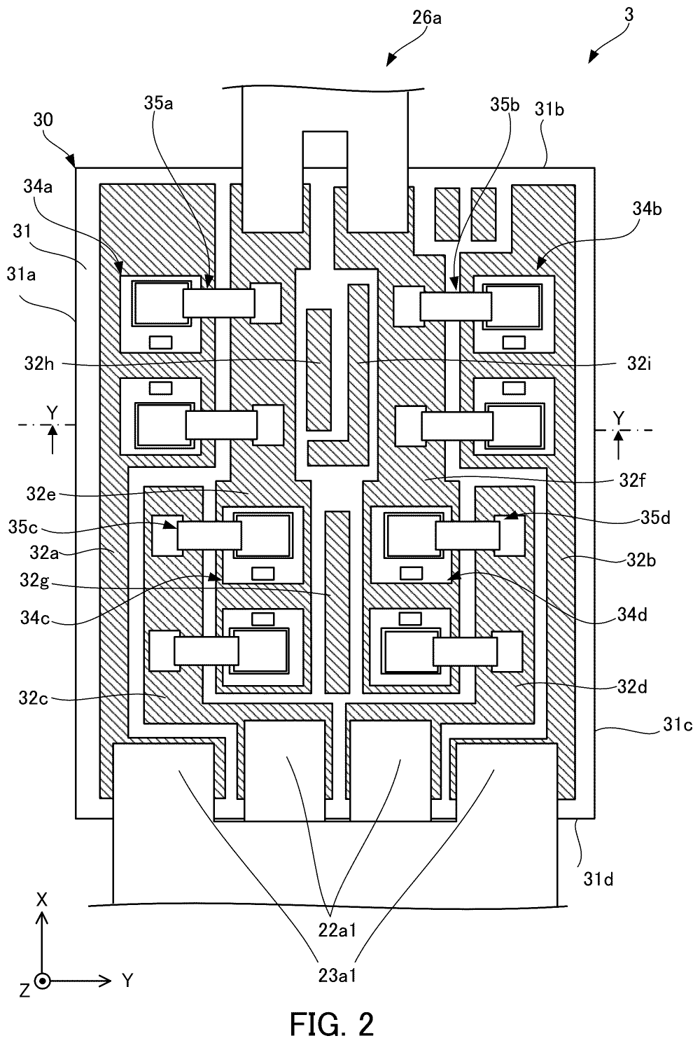

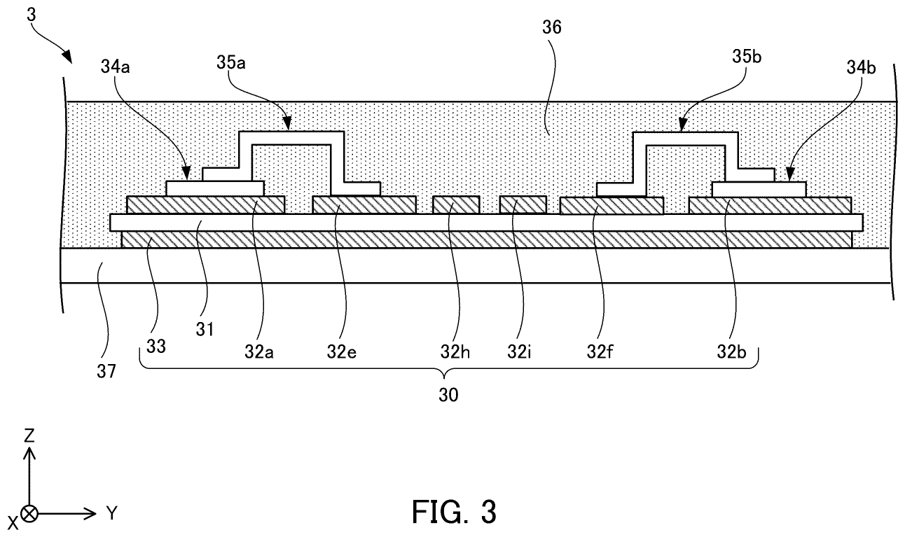

This semiconductor module 2 is an example of an electronic module, and includes semiconductor units (not illustrated), a heat dissipation plate 37 (see FIG. 3) on which the semiconductor units are disposed, and a case 20 that is disposed on the heat dissipation plate and stores the semiconductor units. The semiconductor units will be described later with reference to FIGS. 2 and 3.

The case 20 includes a frame portion 21, terminal stack portions 24, a U terminal 26a, a V terminal 26b, a W terminal 26c, and control terminals 25a, 25b, and 25c. The frame portion 21 has an approximately rectangular shape in plan view, and has first to fourth side portions 21a to 21d in four directions. The frame portion 21 includes storage areas 21e1, 21e2, and 21e3 provided sequentially along the first side portion 21a and the third side portion 21c on its front surface.

The storage areas 21e1, 21e2, and 21e3 are spaces partitioned by the control terminals 25a and 25b on the front surface of the frame portion 21 in plan view and provided along the longitudinal direction (the first and third side portions 21a and 21c) of the frame portion 21. Each of the above-described semiconductor units is stored in a corresponding one of the storage areas 21e1, 21e2, and 21e3. Each of the semiconductor units is electrically bonded to a first terminal 22 and a second terminal 23, which are included in a corresponding one of the terminal stack portions described later, and is also electrically bonded to a corresponding one of the U terminal 26a, the V terminal 26b, and the W terminal 26c in the storage areas 21e1, 21e2, and 21e3. Although not illustrated, the semiconductor units are electrically connected to the control terminals 25a, 25b, and 25c by wires.

When the semiconductor units are stored in the storage areas 21e1, 21e2, and 21e3 as described above, the storage areas 21e1, 21e2, and 21e3 are sealed by a sealing member 36 as illustrated in FIG. 1. The sealing member 36 contains a thermosetting resin and a filler contained in the thermosetting resin. Examples of the thermosetting resin include an epoxy resin, a phenol resin, and a maleimide resin. The filler is, for example, silicon oxide, aluminum oxide, boron nitride, or aluminum nitride.

The frame portion 21 including the three terminal stack portions 24, the U terminal 26a, the V terminal 26b, the W terminal 26c, and the control terminals 25a, 25b, and 25c is formed by injection molding using a thermoplastic resin. Alternatively, the control terminals 25a, 25b, and 25c may be formed separately from the frame portion 21 by being included in a thermosetting resin on which injection molding is performed. The control terminals 25a, 25b, and 25c integrally molded with the resin in this manner may be attached to the opening on the front surface of the frame portion 21, so as to form the storage areas 21e1, 21e2, and 21e3. The control terminals 25a, 25b, and 25c are attached to the +Y direction side portions of the storage areas 21e1, 21e2, and 21e3 and are parallel to the lateral direction (the second and fourth side portions 21b and 21d) of the case 20. The thermoplastic resin is, for example, a polyphenylene sulfide (PPS) resin, a polybutylene terephthalate (PBT) resin, a polybutylene succinate (PBS) resin, a polyamide (PA) resin, or an acrylonitrile butadiene styrene (ABS) resin. The storage areas 21e1, 21e2, and 21e3 will be described as the storage area 21e when they are not particularly distinguished from each other.

The three terminal stack portions 24 are provided along the longitudinal direction (the first side portion 21a) of the frame portion 21. Each of the terminal stack portions 24 is provided for a corresponding one of the storage areas 21e1, 21e2, and 21e3, and is exposed on the first side portion 21a. The individual terminal stack portion 24 includes a first terminal 22 and a second terminal 23 stacked on the first terminal 22 with one end portion of the front surface of the first terminal 22 exposed.

The front surface of one end portion of the individual first terminal 22 appears from the first side portion 21a and faces upward (±Z direction). The other end portion of the first terminal 22 is electrically connected to portions corresponding to the negative electrodes of semiconductor chips of a corresponding semiconductor unit inside the storage area 21e of the case 20. The second terminal 23 is disposed on the first terminal 22 such that one end portion of the first terminal 22 is exposed. The front surface of one end portion of the individual second terminal 23 appears from the first side portion 21a and faces upward (±Z direction). The other end portion of the second terminal 23 is electrically connected to portions corresponding to the positive electrodes of the semiconductor chips inside the storage area 21e of the case 20.

The first terminal 22 and the second terminal 23 are made of a metal having excellent electric conductivity. The metal is, for example, copper or a copper alloy. An oxide film is formed on the surface of each of the first terminal 22 and the second terminal 23. Accordingly, the insulation between the first terminal 22 and the second terminal 23 is maintained. The details of the terminal stack portion 24 will be described later.

One end portion of each of the control terminals 25a, 25b, and 25c extends in the upward direction (±Z direction) of the semiconductor module 2. The other end of each of the control terminals 25a, 25b, and 25c is electrically connected to a corresponding one of the control electrodes of the semiconductor chips of the semiconductor units in the storage areas 21e1, 21e2, and 21e3. The control terminals 25a, 25b, and 25c are made of a metal having excellent electric conductivity. Examples of the metal include copper, a copper alloy, aluminum, and an aluminum alloy. Plating may be performed to improve the corrosion resistance of the control terminals 25a, 25b, and 25c. In this case, the plating material used is, for example, nickel, a nickel-phosphorus alloy, or a nickel-boron alloy.

The U terminal 26a, the V terminal 26b, and the W terminal 26c are provided along the longitudinal direction (the third side portion 21c) of the frame portion 21. Each of the U terminal 26a, the V terminal 26b, and the W terminal 26c is provided for a corresponding one of the storage areas 21e1, 21e2, and 21e3, and is exposed on the third side portion 21c. The front surface of one end portion of each of the U terminal 26a, the V terminal 26b, and the W terminal 26c appears from the third side portion 21c and faces upward (±Z direction). The other end of each of the U terminal 26a, the V terminal 26b, and the W terminal 26c is electrically connected to a portion corresponding to a corresponding one of the output electrodes of the semiconductor chips of the semiconductor units in the storage areas 21e1, 21e2, and 21e3. The U terminal 26a, the V terminal 26b, and the W terminal 26c are made of a metal having excellent electric conductivity. The metal is, for example, copper or a copper alloy. In order to improve the corrosion resistance of the U terminal 26a, the V terminal 26b, and the W terminal 26c, plating may be performed. In this case, the plating material used is, for example, nickel, a nickel-phosphorus alloy, or a nickel-boron alloy.

Next, the semiconductor units included in the semiconductor module 2 will be described with reference to FIGS. 2 and 3. FIG. 2 is a plan view of a semiconductor unit according to the first embodiment. FIG. 3 is a cross-sectional view of the semiconductor unit according to the first embodiment. FIG. 3 is a cross-sectional view taken along a dashed-dotted line Y-Y in FIG. 2.

As illustrated in FIG. 3, a semiconductor unit 3 is disposed on the heat dissipation plate 37 via a bonding member (not illustrated). The case 20 is disposed on the heat dissipation plate 37 via an adhesive, and the semiconductor units 3 are stored in the storage areas 21e1, 21e2, and 21e3 of the case 20. The semiconductor unit 3 in FIG. 2 includes an insulated circuit substrate 30, semiconductor chips 34a to 34d, and lead frames 35a to 35d.

Solder or a sintered material is used as the bonding member that bonds the heat dissipation plate 37 and the semiconductor unit 3 (the insulated circuit substrate 30). As the solder, lead-free solder or lead-containing solder is used. The lead-free solder contains, for example, an alloy containing at least two of tin, silver, copper, zinc, antimony, indium, and bismuth as a main component. Further, the solder may contain an additive. The additive is, for example, nickel, germanium, cobalt, or silicon. By using solder containing an additive, wettability, gloss, and bonding strength are improved, and reliability is consequently improved. The lead-containing solder further contains lead. As the sintered material, for example, a metal material containing at least one of copper, a copper alloy, nickel, a nickel alloy, silver, and a silver alloy is used.

The insulated circuit substrate 30 has a rectangular shape in plan view. The insulated circuit substrate 30 includes an insulating plate 31, a metal plate 33 formed on the rear surface of the insulating plate 31, and a plurality of wiring plates 32a to 32i formed on the front surface of the insulating plate 31. The outer shapes of the plurality of wiring plates 32a to 32i and the metal plate 33 are smaller than the outer shape of the insulating plate 31, and are formed inside the insulating plate 31 in plan view. The shape, the number, and the size of the plurality of wiring plates 32a to 32i are examples.

The insulating plate 31 has a rectangular shape in plan view. Corner portions of the insulating plate 31 may be chamfered. For example, the insulating plate 31 may have chamfered or rounded corner portions. The insulating plate 31 has a long side 31a, a short side 31b, a long side 31c, and a short side 31d, which are outer peripheral sides, in four directions. The insulating plate 31 is made of ceramics having good thermal conductivity. The ceramics includes, for example, a material containing aluminum oxide, aluminum nitride, or silicon nitride as a main component.

The metal plate 33 has a rectangular shape in plan view. Further, corner portions of the metal plate 33 may be, for example, chamfered or rounded. The metal plate 33 is smaller in size than the insulating plate 31 and is formed on the entire rear surface of the insulating plate 31 except for the edge portion thereof. The metal plate 33 is mainly made of a metal having excellent thermal conductivity. The metal is, for example, copper, aluminum, or an alloy containing at least one of these metals. In order to improve the corrosion resistance of the metal plate, plating may be performed. In this case, the plating material used is, for example, nickel, a nickel-phosphorus alloy, or a nickel-boron alloy.

The wiring plates 32a to 32i are formed over the entire surface of the insulating plate 31 except for the edge portion thereof. Preferably, in plan view, end portions of the wiring plates 32a to 32f, the end portions facing the outer periphery of the insulating plate 31, overlap end portions of the metal plate 33, the end portions facing the outer periphery of the insulating plate 31. Therefore, the stress balance between the wiring plates 32a to 32i on the front surface of the insulating plate 31 of the insulated circuit substrate 30 and the metal plate 33 on the rear surface of the insulating plate 31 of the insulated circuit substrate 30 is maintained. Damage such as excessive warpage and cracking of the insulating plate 31 is suppressed. The wiring plates 32a to 32i are made of a metal having excellent electric conductivity. The metal is, for example, copper, aluminum, or an alloy containing at least one of these metals. The surfaces of the wiring plates 32a to 32i may be plated to improve corrosion resistance. In this case, the plating material used is, for example, nickel, a nickel-phosphorus alloy, or a nickel-boron alloy.

The wiring plate 32a is formed near a long side 31a of the insulating plate 31 from a short side 31b to a short side 31d along the long side 31a. The wiring plate 32a has a recess in its side located in the direction of the long side 31c, the recess being located in a lower portion (−X direction) of the wiring plate 32a. The wiring plate 32b is approximately line-symmetrical to the wiring plate 32a with respect to the center line in the ±Y directions. The wiring plate 32b is formed near the long side 31c of the insulating plate 31 from the short side 31b to the short side 31d along the long side 31c. The wiring plate 32b has a recess in its side located in the direction of the long side 31a, the recess being located in a lower portion (−X direction) of the wiring plate 32b.

The wiring plate 32c is disposed in an area surrounded by the lower portion (−X direction) of the wiring plate 32a, the lower portion (−X direction) of the wiring plate 32e, the short side 31d, and the wiring plate 32e. That is, the wiring plate 32c has an approximately L-shape. The wiring plate 32d is approximately line-symmetrical to the wiring plate 32c with respect to the center line in the ±Y directions. The wiring plate 32d is disposed in an area surrounded by the lower portion (−X direction) of the wiring plate 32b, the wiring plate 32f, the short side 31d, and the wiring plate 32f. That is, the wiring plate 32d has an approximately L-shape.

The wiring plate 32e is adjacent to the wiring plate 32a and extends in the −X direction from the short side 31b along the long side 31a. The −X direction end portion of the wiring plate 32e is located away from the short side 31d. The wiring plate 32e has a recess in its side located in the direction of the long side 31c, the recess being located in an upper portion (±X direction) of the wiring plate 32e. The wiring plate 32f is approximately line-symmetrical to the wiring plate 32e with respect to the center line in the ±Y directions. The wiring plate 32f is adjacent to the upper portion (±X direction) of the wiring plate 32b and extends in the −X direction from the short side 31b along the long side 31c. The −X direction end portion of the wiring plate 32f is located away from the short side 31d. The wiring plate 32f has a recess in its side located in the direction of the long side 31a, the recess being located in an upper portion (±X direction) of the wiring plate 32f.

The wiring plate 32g has an I-shape in plan view and is disposed between the wiring plates 32e and 32f in parallel to the long sides 31a and 31c. The wiring plate 32h has an I-shape in plan view, and is disposed in parallel to the long side 31a near the wiring plate 32e in an area surrounded by the recesses of the wiring plates 32e and 32f. The wiring plate 32i has an L-shape in plan view, and is disposed in parallel to the long side 31c near the wiring plate 32f in an area surrounded by the recesses of the wiring plates 32e and 32f. The wiring plate 32i is disposed so as to surround two sides of the wiring plate 32h, one being located in the direction of the long side 31c and the other being located in the direction of the short side 31d.

In addition, second connection portions 23al of the second terminal 23 are bonded to the lower end portions (−X direction) of the wiring plates 32a and 32b of the insulated circuit substrate 30. First connection portions 22al of the first terminal 22 are bonded to the lower end portions (−X direction) of the wiring plates 32c and 32d of the insulated circuit substrate 30. The upper end portions (±X direction) of the wiring plates 32e and 32f of the insulated circuit substrate are bonding portions to which a corresponding one of the U terminal 26a, the V terminal 26b, and the W terminal 26c is bonded. FIG. 2 illustrates a case where the U terminal 26a is bonded to each of the wiring plates 32e and 32f.

As the insulated circuit substrate 30 having the above-described configuration, for example, a direct copper bonding (DCB) substrate or an active metal brazed (AMB) substrate may be used. The insulated circuit substrate 30 dissipates heat generated by the semiconductor chips 34a to 34d, which will be described later, by conducting the heat to the rear surface of the insulated circuit substrate 30 via the wiring plates 32a, 32b, 32e, and 32f, the insulating plate 31, and the metal plate 33.

The semiconductor chips 34a to 34d are power devices made of silicon carbide. For example, the power devices are power metal-oxide-semiconductor field-effect transistors (MOSFETs). In the individual power MOSFET, the body diode functions as a freewheeling diode (FWD). Each of the semiconductor chips 34a to 34d includes a drain electrode as an input electrode (a main electrode) on the rear surface, and a gate electrode as a control electrode and a source electrode as an output electrode (a main electrode) on the front surface.

The semiconductor chips 34a to 34d may be power devices made of silicon. Examples of the individual power device in this case include a reverse conducting (RC)-insulated gate bipolar transistor (IGBT). The RC-IGBT is formed by forming an IGBT as a switching element and an FWD as a diode element in one chip. Each of the semiconductor chips 34a to 34d includes, for example, a collector electrode as an input electrode (a main electrode) on the rear surface, a gate electrode as a control electrode and an emitter electrode as an output electrode (a main electrode) on the front surface.

According to the present embodiment, the plurality of the semiconductor chips 34a to 34d are disposed on the wiring plates 32a, 32b, 32e, and 32f via the bonding members described above. FIG. 2 illustrates a case where two semiconductor chips are disposed on an individual wiring plate. In this case, the semiconductor chips 34a are disposed such that their control electrodes face each other. The semiconductor chips 34b to 34d are also disposed in the same way. The lead frames 35a to 35d electrically connect the output electrodes on the front surfaces of the semiconductor chips 34a to 34d to the wiring plates 32e, 32f, 32c, and 32d. The lead frames 35a electrically and mechanically connect the semiconductor chips 34a and the wiring plate 32e. The lead frames 35b electrically and mechanically connect the semiconductor chips 34b and the wiring plate 32f. The lead frames 35c electrically and mechanically connect the semiconductor chips 34c and the wiring plate 32c. The lead frames 35d electrically and mechanically connect the semiconductor chips 34d and the wiring plate 32d.

One end portion of each of the lead frames 35a to 35d is bonded to the output electrode of a corresponding one of the semiconductor chips 34a to 34d by the above-described solder as a bonding member. The other end of each of the lead frames 35a to 35d is bonded to a corresponding one of the wiring plates 32e, 32f, 32c, and 32d by using the bonding member described above. Alternatively, the bonding may be performed by ultrasonic welding or laser welding. The lead frames 35a to 35d are made of a material having excellent electric conductivity. Examples of the material include copper, aluminum, and an alloy containing at least one of these elements. The surfaces of the lead frames 35a to 35d may be plated to improve corrosion resistance. The plating material in this case is, for example, nickel, a nickel-phosphorus alloy, or a nickel-boron alloy.

The heat dissipation plate 37 has a rectangular shape in plan view and corresponds to the outer shape of the rear surface of the case 20. The semiconductor units 3 are bonded to the front surface of the heat dissipation plate 37 along the longitudinal direction by bonding members. The heat dissipation plate 37 is mainly made of a metal having excellent thermal conductivity. The metal is, for example, copper, aluminum, or an alloy containing at least one of these metals. In order to improve the corrosion resistance of the metal plate, plating may be performed. In this case, the plating material used is, for example, nickel, a nickel-phosphorus alloy, or a nickel-boron alloy.

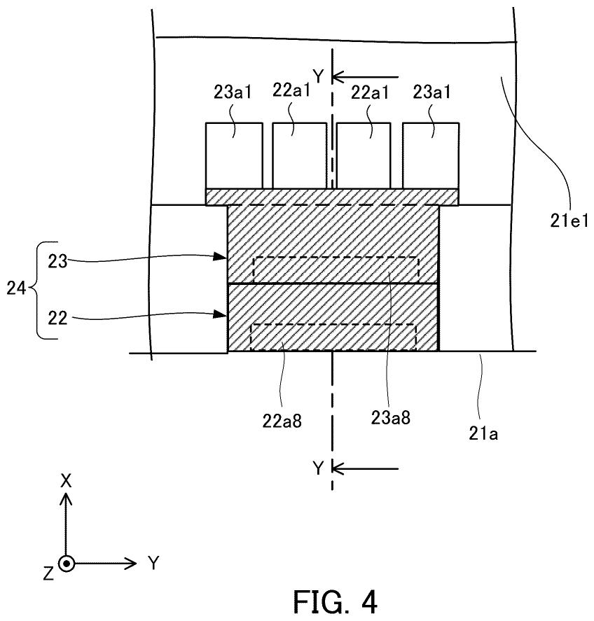

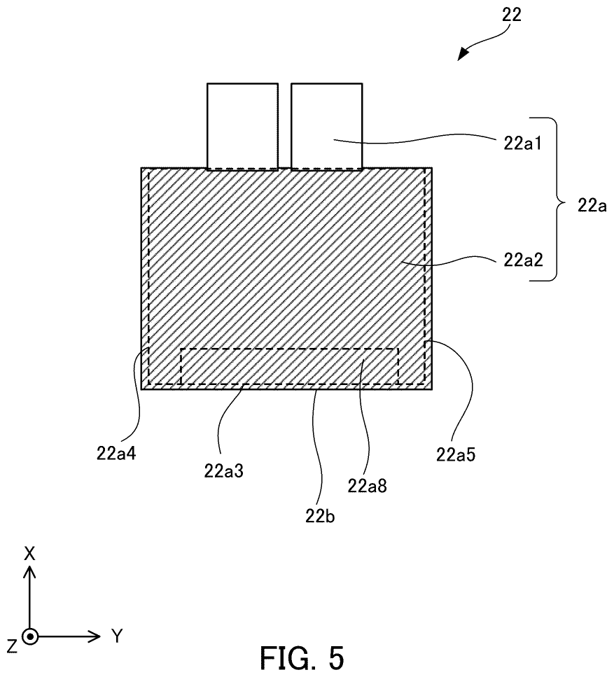

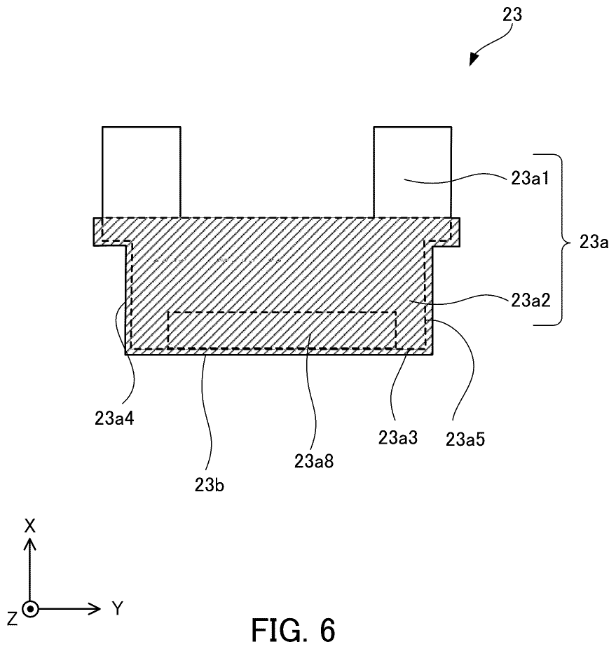

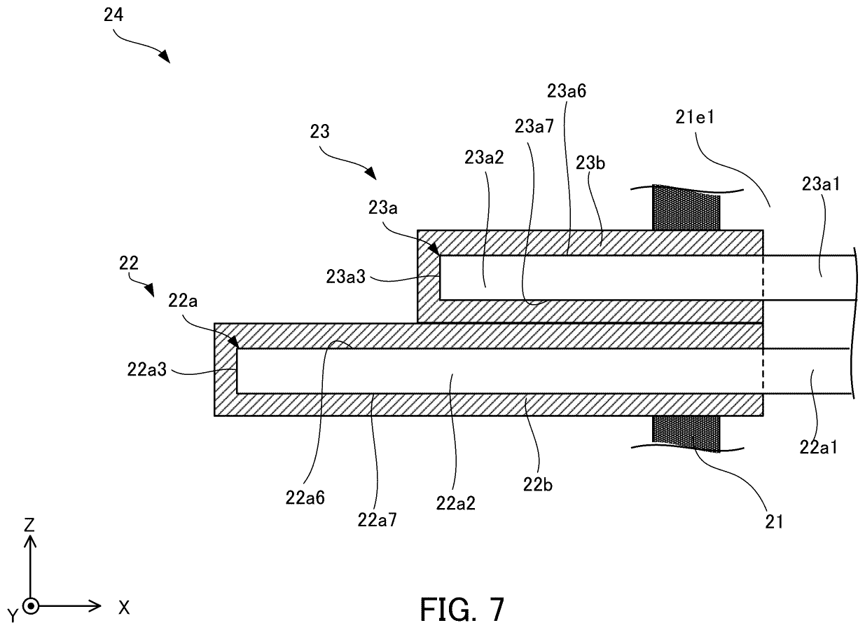

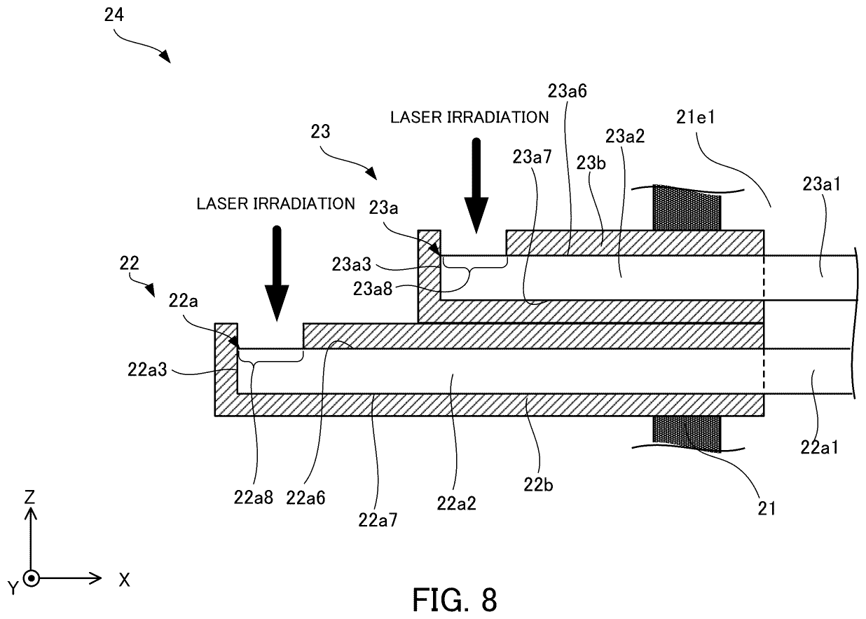

Next, details of the terminal stack portions 24 will be described with reference to FIGS. 4 to 8. FIG. 4 is a plan view of a terminal stack portion according to the first embodiment. FIG. 5 is a plan view of a first terminal included in the terminal stack portion according to the first embodiment, and FIG. 6 is a plan view of a second terminal included in the terminal stack portion according to the first embodiment. FIG. 7 is a cross-sectional view of the terminal stack portion according to the first embodiment, and FIG. 8 is a cross-sectional view of the terminal stack portion from which bonding areas are removed according to the first embodiment. FIGS. 7 and 8 are cross-sectional views taken along an alternate long and short dash line Y-Y in FIG. 4.

As illustrated in FIG. 4, the individual terminal stack portion 24 includes a first terminal 22 and a second terminal 23. In the terminal stack portion 24, as illustrated in FIG. 7, the flat plate-shaped second terminal 23 is stacked on the flat plate-shaped first terminal 22. A front end surface 22a3 of the first terminal 22 extends further outward (−X direction) beyond a front end surface 23a3 of the second terminal 23, and an area corresponding to a first bonding area 22a8 included in the first terminal 22 is exposed. The terminal stack portion 24 is fixed to the frame portion 21 such that the front end surface 22a3 of the first terminal 22 is flush with the first side portion 21a of the frame portion 21.

As illustrated in FIG. 5, the first terminal 22 includes a first conductive plate 22a and a first oxide film 22b. The first conductive plate 22a integrally includes first connection portions 22al and a first wiring portion 22a2. The first oxide film 22b covers the surface of the first wiring portion 22a2. The first wiring portion 22a2 is a rectangular portion indicated by a broken line in the first oxide film 22b in FIG. 5.

The first wiring portion 22a2 has a flat plate shape and includes the front end surface 22a3, first side surfaces 22a4 and 22a5, a first front surface 22a6, and a first rear surface 22a7. The first front surface 22a6 and the first rear surface 22a7 have a rectangular shape in plan view and have the same size. The first bonding area 22a8 is set along the front end surface 22a3 in plan view on the outer side (−X direction) of the first front surface 22a6. The first bonding area 22a8 is an area surrounded by a broken line on the −X direction side of the first front surface 22a6 in FIG. 5. The first bonding area 22a8 is an area that is bonded to a corresponding one of first, second, and third connection portions 43a, 43b, and 43c of a first connection terminal 43, which is an example of a fifth conductive plate included in a capacitor 4 described later. For example, the first bonding area 22a8 has a rectangular shape in plan view. The ±Y direction width of the first bonding area 22a8 is smaller than the ±Y direction width of the first front surface 22a6. The first bonding area 22a8 has a predetermined length from the front end surface 22a3 in the inner direction (in the ±X direction).

The front end surface 22a3 is the outermost end portion of the terminal stack portion 24 in the extending direction (−X direction). That is, the front end surface 22a3 is formed by the −X direction sides of the first front surface 22a6 and the first rear surface 22a7. The front end surface 22a3 is approximately parallel to the first side portion 21a and the third side portion 21c of the frame portion 21 of the case 20.

The first side surfaces 22a4 and 22a5 are formed by the ±Y direction sides of the first front surface 22a6 and the first rear surface 22a7. In other words, each of the first side surfaces 22a4 and 22a5 continuously extends from one of the ±Y direction sides of a corresponding one of the first front surface 22a6 and the first rear surface 22a7 and is connected to the other one of the ±Y direction sides. The first side surfaces 22a4 and 22a5 are parallel to the extending direction (±X direction) of the terminal stack portion 24. That is, the first side surfaces 22a4 and 22a5 are approximately parallel to the second side portion 21b and the fourth side portion 21d of the frame portion 21 of the case 20. In addition, a rear end surface (its reference character is omitted) opposite to the front end surface 22a3 is formed by the ±X direction sides of the first front surface 22a6 and the first rear surface 22a7.

The first connection portions 22al have a rectangular shape in plan view. The first connection portions 22al have the same thickness as the first wiring portion 22a2. The first connection portions 22al are formed on the rear end surface of the first wiring portion 22a2, the rear end surface being opposite to the front end surface 22a3, and extend in the ±X direction by a predetermined length. The two first connection portions 22al are arranged in the central portion of the rear end surface of the first wiring portion 22a2 with a predetermined gap therebetween in the ±Y direction.

The first conductive plate 22a is made of a metal having excellent electric conductivity. The metal is, for example, copper or an alloy containing copper as a main component. The first conductive plate 22a has an approximately uniform thickness as a whole, which is, for example, 0.8 mm or more and 1.2 mm or less, for example, 1.0 mm.

The first oxide film 22b is provided on the surface of the first wiring portion 22a2 of the first conductive plate 22a. That is, the first oxide film 22b is provided on each of the front end surface 22a3, the first side surfaces 22a4 and 22a5, the first front surface 22a6, and the first rear surface 22a7 of the first wiring portion 22a2. The first oxide film 22b may be formed on the rear end surface opposite to the front end surface 22a3 of the first conductive plate 22a. The first oxide film 22b is not formed on the first connection portions 22al of the first conductive plate 22a. The first oxide film 22b is an example of a metal oxide layer, and is mainly made of an insulating material. The material is a metal oxide, for example, an aluminum oxide layer. The first oxide film 22b is illustrated as a single layer. A surface of the first conductive plate 22a, the surface corresponding to the first oxide film 22b, which is the aluminum oxide layer, may include an aluminum layer.

As illustrated in FIG. 6, the second terminal 23 includes a second conductive plate 23a and a second oxide film 23b. The second conductive plate 23a integrally includes second connection portions 23al and a second wiring portion 23a2. The second oxide film 23b covers the surface of the second wiring portion 23a2. The second wiring portion 23a2 is a T-shaped portion indicated by a broken line in the second oxide film 23b in FIG. 6.

The second wiring portion 23a2 has a flat plate shape and includes the front end surface 23a3, second side surfaces 23a4 and 23a5, a second front surface 23a6, and a second rear surface 23a7. The second front surface 23a6 and the second rear surface 23a7 have a T-shape in plan view and have the same size. A second bonding area 23a8 is set along the front end surface 23a3 in plan view on the outer side (−X direction) of the second front surface 23a6. In FIG. 6, the second bonding area 23a8 is an area surrounded by a broken line on the −X direction side of the second front surface 23a6, and faces the first bonding area 22a8. The second bonding area 23a8 corresponds to the size of a corresponding one of coupling members 41a, 41b, and 41c included in the capacitor 4 described later. For example, the second bonding area 23a8 has a rectangular shape in plan view. The ±Y direction width of the second bonding area 23a8 is smaller than the ±Y direction width of the second front surface 23a6. The second bonding area 23a8 has a predetermined length from the front end surface 23a3 in the inner direction (in the ±X direction).

The front end surface 23a3 is the outermost end portion of the terminal stack portion 24 in the extending direction (−X direction). That is, the front end surface 23a3 is formed by the −X direction sides of the second front surface 23a6 and the second rear surface 23a7. The front end surface 23a3 is approximately parallel to the first side portion 21a and the third side portion 21c of the frame portion 21 of the case 20.

The second side surfaces 23a4 and 23a5 are formed by the ±Y direction sides of the second front surface 23a6 and the second rear surface 23a7. In other words, each of the second side surfaces 23a4 and 23a5 continuously extends from one of the ±Y direction sides of a corresponding one of the second front surface 23a6 and the second rear surface 23a7 to the other one of the ±Y direction sides. The second side surfaces 23a4 and 23a5 are parallel to the extending direction (−X direction) of the terminal stack portion 24. That is, the second side surfaces 23a4 and 23a5 are approximately parallel to the second side portion 21b and the fourth side portion 21d of the frame portion 21 of the case 20. In addition, a rear end surface (its reference character is omitted) opposite to the front end surface 23a3 is formed in the ±X direction sides of the second front surface 23a6 and the second rear surface 23a7.

The second connection portions 23al have a rectangular shape in plan view. The second connection portions 23al have the same thickness as the second wiring portion 23a2. The second connection portions 23al are formed on the rear end surface of the second wiring portion 23a2, the rear end surface being opposite to the front end surface 23a3, and extend in the ±X direction by a predetermined length. The two second connection portions 23al are formed at the ±Y direction ends of the rear end surface of the second wiring portion 23a2. The second connection portions 23al may have the same thickness and the same size as the first connection portions 22a1. When the second terminal 23 is disposed on the first terminal 22, the second connection portions 23al are located outside the first connection portions 22al, as illustrated in FIG. 4.

The second conductive plate 23a is made of a metal having excellent electric conductivity. The metal is, for example, copper or an alloy containing copper as a main component. The second conductive plate 23a has an approximately uniform thickness as a whole, which is, for example, 0.8 mm or more and 1.2 mm or less, for example, 1.0 mm.

The second oxide film 23b is provided on the surface of the second wiring portion 23a2 of the second conductive plate 23a. That is, the second oxide film 23b is formed on each of the front end surface 23a3, the second side surfaces 23a4 and 23a5, the second front surface 23a6, and the second rear surface 23a7 of the second wiring portion 23a2. The second oxide film 23b may be provided on the rear end surface opposite to the front end surface 23a3 of the second conductive plate 23a. The second oxide film 23b is not formed on the second connection portions 23al of the second conductive plate 23a. The second oxide film 23b is an example of a metal oxide layer, and is made of the same material as the first oxide film 22b. Also in this case, a surface of the second conductive plate 23a, the surface corresponding to the second oxide film 23b, which is the aluminum oxide layer, may include an aluminum layer.

As described above, the individual terminal stack portion 24 is formed integrally with the frame portion 21. As illustrated in FIG. 7, in the terminal stack portion 24, a portion corresponding to the first wiring portion 22a2 included in the first terminal 22 and a portion corresponding to the second wiring portion 23a2 included in the second terminal 23 are fixed to the frame portion 21. The first connection portions 22al of the first terminal 22 and the second connection portions 23al of the second terminal 23 are disposed in the storage area 21e of the frame portion 21.

The first connection portions 22al of the first terminal 22 are bonded to the wiring plates 32c and 32d of the insulated circuit substrate 30 stored in the storage area 21e, and are electrically connected to the output electrodes (the negative electrodes) of the semiconductor chips 34c and 34d (see FIG. 2). The second connection portions 23al of the second terminal 23 are bonded to the wiring plates 32a and 32b of the insulated circuit substrate 30 stored in the storage area 21e, and are electrically connected to the input electrodes (the positive electrodes) of the semiconductor chips 34a and 34b (see FIG. 2). For example, ultrasonic bonding, laser welding, or a bonding member (for example, solder or a sintered body) is used to bond the first connection portions 22al and the second connection portions 23al to their respective wiring plates.

The first terminal 22 and the second terminal 23 of the terminal stack portion 24 are stacked via the first oxide film 22b and the second oxide film 23b. Therefore, the insulation between the first conductive plate 22a of the first terminal 22 and the second conductive plate 23a of the second terminal 23 is maintained. Therefore, the first oxide film 22b and the second oxide film 23b each have a thickness that secures a creepage distance between the first terminal 22 and the second terminal 23 and that sufficiently maintains the insulation. For example, when the dielectric breakdown voltage between the first terminal 22 and the second terminal 23 is 1 kV or more, the total thickness of the first oxide film 22b and the second oxide film 23b between the first terminal 22 and the second terminal 23 is 20 μm or more. Details of a method of coating the first conductive plate 22a and the second conductive plate 23a with the first oxide film 22b and the second oxide film 23b will be described later.

In addition, only one of the first oxide film 22b and the second oxide film 23b may be provided if the insulation between the first terminal 22 and the second terminal 23 is sufficiently maintained. In order to maintain the insulation between the first terminal 22 and the second terminal 23, the first oxide film 22b may be provided only on the first side surfaces 22a4 and 22a5 and the first front surface 22a6. Alternatively, the second oxide film 23b may be provided only on the second side surfaces 23a4 and 23a5 and the second rear surface 23a7.

In order to maintain the insulation between the first conductive plate 22a and the second conductive plate 23a, an insulating member needs to be provided between the first wiring portion 22a2 of the first conductive plate 22a and the second wiring portion 23a2 of the second conductive plate 23a. When the insulating member is, for example, a sheet-like insulating paper, a sufficient creepage distance between the first terminal 22 (the first conductive plate 22a) and the second terminal 23 (the second conductive plate 23a) is secured, and the insulation between the first terminal 22 and the second terminal 23 is consequently maintained. However, the insulating paper has low moisture resistance. Therefore, when the use period becomes long, the insulation between the first terminal 22 and the second terminal 23 may fail to be maintained. The insulating paper may include a thin portion. In such a portion, dielectric breakdown may occur due to the voltage between the first terminal 22 and the second terminal 23.

On the other hand, in the semiconductor module 2, the first oxide film 22b and the second oxide film 23b are used as insulating members between the first wiring portion 22a2 of the first conductive plate 22a and the second wiring portion 23a2 of the second conductive plate 23a. Thus, the moisture resistance is improved. Therefore, even if the use period becomes long, it is possible to suppress a decrease in insulation between the first terminal 22 and the second terminal 23.

Furthermore, the adhesiveness between the first oxide film 22b and the second oxide film 23b, which are oxide layers, and the thermoplastic resin constituting the frame portion 21 is better than when an insulating paper is used. Therefore, the adhesion between the individual terminal stack portion 24 and the case 20 is improved. In addition, the first oxide film 22b and the second oxide film 23b, which are oxide layers, are less likely to cause dielectric breakdown than when insulating paper is used.

In addition, since the insulation between the first conductive plate 22a of the first terminal 22 and the second conductive plate 23a of the second terminal 23 is maintained by the first oxide film 22b and the second oxide film 23b, no additional insulating member is needed between the first terminal 22 and the second terminal 23. Therefore, the terminal stack portion 24 is reduced in size, and the semiconductor module 2 is consequently reduced in size.

A positive electrode terminal is bonded to the first bonding area 22a8 of the first terminal 22, and a negative electrode terminal is bonded to the second bonding area 23a8 of the second terminal 23. In this way, the energization direction in the first terminal 22 and the energization direction in the second terminal 23 are opposite to each other. In this way, the inductance is canceled out, and as a result, an inductance reduction effect is obtained. Here, in the present embodiment, since it is possible to shorten the length in the thickness direction between the first terminal 22 and the second terminal 23, the inductance reduction effect is further enhanced, and the inductance between the first terminal 22 and the second terminal 23 is consequently reduced further.

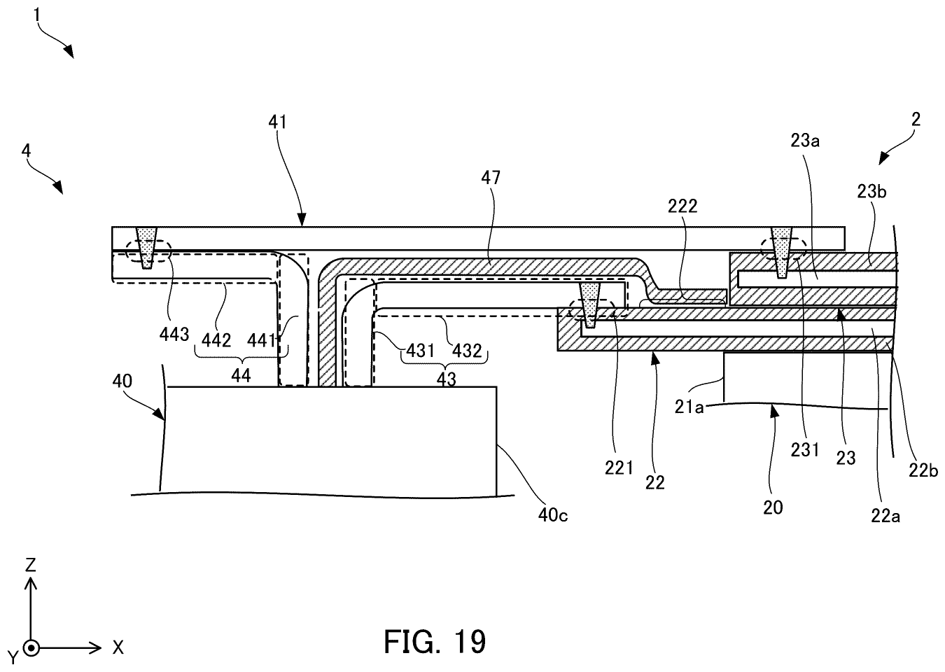

As will be described later, a first connection terminal 43 and a coupling member 41 are bonded to the first terminal 22 and the second terminal 23 of the terminal stack portion 24 (see FIG. 19 to be described later). At this time, for example, laser irradiation is performed on the first oxide film 22b corresponding to the first bonding area 22a8 of the first terminal 22. Similarly, laser irradiation is performed on the second oxide film 23b corresponding to the second bonding area 23a8 of the second terminal 23. As a result, as illustrated in FIG. 8, the first oxide film 22b is removed, and the first bonding area 22a8 of the first conductive plate 22a is exposed. The second oxide film 23b is removed, and the second bonding area 23a8 of the second conductive plate 23a is exposed. In addition, in order to remove the first oxide film 22b and the second oxide film 23b, for example, polishing with a file or cutting with a milling cutter may be used, instead of laser irradiation.

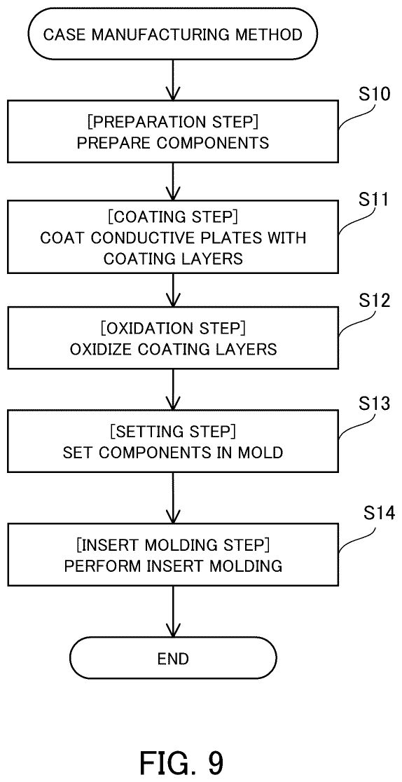

Next, a method of manufacturing the case 20 included in the semiconductor module 2 will be described with reference to FIG. 9. FIG. 9 is a flowchart illustrating a method of manufacturing the case included in the semiconductor module according to the first embodiment. The method of manufacturing the case 20 illustrated in FIG. 9 is included in a method of manufacturing the semiconductor module 2.

To manufacture the case 20, first, a preparation step of preparing various terminals and the case material of the case 20 (the frame portion 21) is performed (step S10). In step S10, in addition to these components, materials, tools, parts, etc., needed for manufacturing the case 20 are prepared as needed. The various terminals include the individual first terminal 22, the individual second terminal 23, the U terminal 26a, the V terminal 26b, the W terminal 26c, and the control terminals 25. The individual first conductive plate 22a and second conductive plate 23a in FIGS. 5 and 6, and the U terminal 26a, the V terminal 26b, and the W terminal 26c in FIG. 1 are acquired from a conductive plate. The terminals are obtained by performing, for example, die-cutting, cutting, or punching on a conductive plate. The conductive plate is made of a metal having excellent electric conductivity, and the metal is, for example, copper or an alloy containing copper as a main component. The case material is, for example, PPS resin.

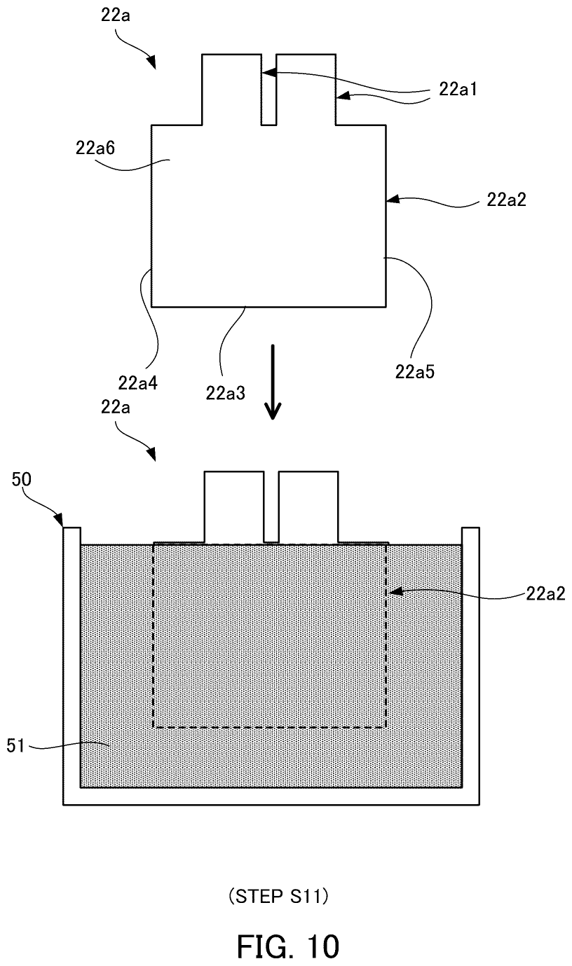

Next, a coating step of coating the individual first conductive plate 22a and second conductive plate 23a with a coating layer is performed (step S11). The individual first terminal 22 and second terminal 23 illustrated in FIGS. 5 and 6 may be manufactured by any one of several methods. Step S11 and the next step S12 are each an example of the manufacturing method. First, an example of the coating step will be described with reference to FIG. 10. FIG. 10 is a diagram illustrating the coating step included in the case manufacturing method according to the first embodiment. In FIG. 10, one of the first conductive plates 22a will be described. The second conductive plates 23a are processed in the same manner.

First, a coating container 50 is filled with solution 51. The solution 51 contains, for example, aluminum. The solution 51 containing aluminum may further contain magnesium or silicon. A first conductive plate 22a is moved vertically downward (toward the solution 51 in the coating container 50) with the front end surface 22a3 facing downward. The first wiring portion 22a2 is immersed in the solution 51 while the first connection portions 22al of the first conductive plate 22a are maintained outside the coating container 50. Consequently, the front end surface 22a3, the first side surfaces 22a4 and 22a5, the first front surface 22a6, and the first rear surface 22a7 (see FIG. 7) of the first wiring portion 22a2 of the first conductive plate 22a come into contact with the solution 51. The rear end surface of the first wiring portion 22a2, the rear end surface being opposite to the front end surface 22a3, may also come into contact with the solution 51. The first connection portions 22al of the first conductive plate 22a do not come into contact with the solution 51.

Although not illustrated, the front end surface 23a3, the second side surfaces 23a4 and 23a5, the second front surface 23a6, and the second rear surface 23a7 of the second wiring portion 23a2 of the second conductive plate 23a also come into contact with the solution 51 while the second connection portions 23al are maintained outside the coating container 50. The second connection portions 23al of the second conductive plate 23a do not come into contact with the solution 51. The rear end surface of the second wiring portion 23a2, the rear end surface being opposite to the front end surface 22a3, may also come into contact with the solution 51.

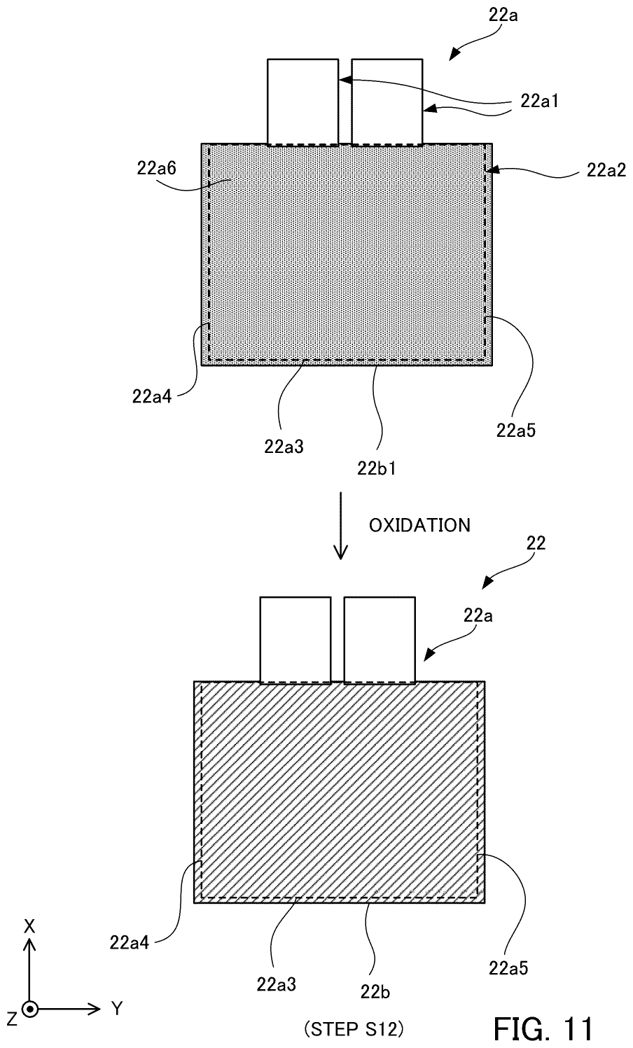

When the first conductive plate 22a immersed in the solution 51 in this manner is taken out from the coating container 50, it is seen that the solution 51 has adhered to the first conductive plate 22a (see the upper portion in FIG. 11). In this way, a coating layer 22b1 is provided on the front end surface 22a3, the first side surfaces 22a4 and 22a5, the first front surface 22a6, and the first rear surface 22a7 of the first wiring portion 22a2 included in the first conductive plate 22a. The coating layer 22b1 contains aluminum.

Similarly, a coating layer is provided on the front end surface 23a3, the second side surfaces 23a4 and 23a5, the second front surface 23a6, and the second rear surface 23a7 of the second wiring portion 23a2 included in the second conductive plate 23a.

Note that the above method is merely an example of the method of coating the first conductive plate 22a and the second conductive plate 23a with a coating layer containing aluminum. Another method may be used as long as the first conductive plate 22a and the second conductive plate 23a are coated with a coating layer containing aluminum. Examples of the method include sputtering, vapor deposition, and plating.

Next, an oxidation step of oxidizing the coating layers of the first conductive plate 22a and the second conductive plate 23a is performed (step S12). In order to oxidize the coating layers provided on the first conductive plate 22a and the second conductive plate 23a in step S11, for example, an anodic oxidation method is performed. The anodic oxidation method is a method in which a current is allowed to flow directly through a conductive plate as an anode in an electrolytic solution, so as to electrically oxidize the conductive plate and to form an oxide layer on the surface thereof. An oxidation step using such an anodic oxidation method will be described with reference to FIG. 11. FIG. 11 is a diagram illustrating an oxidation step included in the case manufacturing method according to the first embodiment. In FIG. 11, one of the first conductive plates 22a will be described. The second conductive plates 23a are processed in the same manner.

The first conductive plate 22a coated with the coating layer 22b1 in step S11 (the upper portion in FIG. 11) is immersed in an electrolytic solution. At this time, the cathode is also included in the electrolytic solution. The cathode may be mainly made of, for example, lead or carbon. Examples of the electrolytic solution include aqueous solutions of oxalic acid, chromic acid, phosphoric acid, and the like. Here, an aqueous oxalic acid solution is used as the electrolytic solution. An oxide film formed by an anodic oxidation method using an aqueous oxalic acid solution has a thick barrier layer, small micropores, and a high dielectric breakdown voltage. When the dielectric breakdown voltage is set to 1 kV or more, the thickness of the oxide layer to be formed needs to be 20 μm or more. By using an aqueous oxalic acid solution as the electrolytic solution, an oxide layer having a thickness realizing such a dielectric breakdown voltage is formed.

In such an electrolytic solution, a positive electrode is applied to the first conductive plate 22a, a negative electrode is applied to the cathode, and a direct current is caused to flow for a predetermined time. The coating layer 22b1 covering the surface of the first wiring portion 22a2 of the first conductive plate 22a is oxidized, and the first oxide film 22b is formed (the lower portion in FIG. 11).

As described above, the first oxide film 22b is formed on the front end surface 22a3, the first side surfaces 22a4 and 22a5, the first front surface 22a6, and the first rear surface 22a7 of the first wiring portion 22a2 of the first conductive plate 22a. Although not illustrated, the second oxide film 23b is similarly formed on the front end surface 23a3, the second side surfaces 23a4 and 23a5, the second front surface 23a6, and the second rear surface 23a7 of the second wiring portion 23a2 of the second conductive plate 23a of the second terminal 23.

The first oxide film 22b and the second oxide film 23b are mainly made of, for example, aluminum oxide. Here, the first oxide film 22b and the second oxide film 23b are each illustrated as a single layer. The aluminum layer may remain on the surfaces of the first wiring portion 22a2 of the first conductive plate 22a and the second wiring portion 23a2 of the second conductive plate 23a, and the first oxide film 22b and the second oxide film 23b may be formed thereon, respectively. Thus, the first terminal 22 and the second terminal 23 are obtained.

In the above-described case, the first oxide film 22b is formed on the front end surface 22a3, the first side surfaces 22a4 and 22a5, the first front surface 22a6, and the first rear surface 22a7 of the first wiring portion 22a2 while the first connection portions 22al of the first terminal 22 are maintained outside the coating container 50. Similarly, the second oxide film 23b is formed on the front end surface 23a3, the second side surfaces 23a4 and 23a5, the second front surface 23a6, and the second rear surface 23a7 of the second wiring portion 23a2 while the second connection portions 23al of the second terminal 23 are maintained outside the coating container 50. When the creepage distance between the first conductive plate 22a and the second conductive plate 23a is secured and the insulation is sufficiently maintained, only the first oxide film 22b or only the second oxide film 23b may be provided. Similarly, the first oxide film 22b may be provided only on the first front surface 22a6 and the first side surfaces 22a4 and 22a5 as long as the insulation is sufficiently maintained. Alternatively, the second oxide film 23b may be provided only on the second rear surface 23a7 and the second side surfaces 23a4 and 23a5. Furthermore, by providing the first oxide film 22b only on the first front surface 22a6 and the first side surfaces 22a4 and 22a5, the second oxide film 23b may be provided only on the second rear surface 23a7 and the second side surfaces 23a4 and 23a5.

In addition, as described with reference to FIG. 8, in order to have the first bonding area 22a8 exposed to the outside on the first front surface 22a6 of the first terminal 22, an area of the first oxide film 22b, the area corresponding to the first bonding area 22a8, is removed by a laser. Instead of such removal, in step S11, the first bonding area 22a8 of the first front surface 22a6 of the first conductive plate 22a may be covered with a mask in advance so as not to come in contact with the solution 51. In this case, a portion corresponding to the first bonding area 22a8 of the first conductive plate 22a is masked using a mask made of a material having a melting point higher than that of aluminum. This prevents the solution 51 from coming into contact with the portion. Thereafter, step S12 is performed in a state where the first bonding area 22a8 of the first conductive plate 22a is masked. In this case, the coating layer is not formed in the area covered with the mask. Next, by removing the mask, the first oxide film 22b is obtained with the first bonding area 22a8 being exposed to the outside on the first front surface 22a6 of the first terminal 22. Similarly, the second oxide film 23b is formed on the second terminal 23 with the second bonding area 23a8 being exposed to the outside.

Next, a setting step of setting components in a mold for the case is performed (step S13). The components are the first terminals 22, the second terminals 23, the U terminal 26a, the V terminal 26b, the W terminal 26c, and the control terminals. When the first terminals 22 and the second terminals 23 are set, the terminal stack portions 24 each of which is formed by disposing a second terminal 23 on a first terminal 22, are set.

Next, an insert molding step of injecting a case material into the mold for the case is performed (step S14). The mold in which the components are set in step S13 is filled with a case material, and the case material is cured. Here, the case material is, for example, PPS resin. After the case material is cured, the mold is removed to obtain the case 20 illustrated in FIG. 1.

The case 20 thus manufactured is set on the heat dissipation plate 37 to which the semiconductor units 3 are bonded. The semiconductor units 3 are consequently stored in the storage areas 21e1, 21e2, and 21e3 of the case 20. The semiconductor module 2 is obtained by a wiring step of electrically connecting the semiconductor units 3 and various terminals of the case 20 and filling the storage areas 21e1, 21e2, and 21e3 with a sealing member.

The semiconductor module 2 includes: a first conductive plate 22a which contains copper or a copper alloy as a main component; a second conductive plate which has a second rear surface 23a7 that faces the first conductive plate 22a and side surfaces that extend continuously from the second rear surface 23a7, and which contains copper or a copper alloy as a main component; and an electrically insulating second oxide film 23b which is provided on the rear surface and the side surfaces of the second conductive plate and which contains a metal oxide of an element different from a metal of the second conductive plate 23a. The first oxide film 22b and the second oxide film 23b are used as the insulating members between the first wiring portion 22a2 of the first conductive plate 22a and the second wiring portion 23a2 of the second conductive plate 23a. As a result, the moisture resistance is improved. Therefore, even if the use period becomes long, it is possible to suppress a decrease in insulation between the first terminal 22 and the second terminal 23.

Furthermore, the adhesiveness between the first oxide film 22b and the second oxide film 23b and the thermoplastic resin constituting the frame portion 21 is better than when an insulating paper is used. Therefore, the adhesion between the individual terminal stack portion 24 and the case 20 is improved. In addition, the first oxide film 22b and the second oxide film 23b are less likely to cause dielectric breakdown than when an insulating paper is used.

In addition, since the insulation between the first conductive plate 22a of the first terminal 22 and the second conductive plate 23a of the second terminal 23 is maintained by the first oxide film 22b and the second oxide film 23b, no additional insulating member is needed between the first terminal 22 and the second terminal 23. Therefore, the terminal stack portion 24 is reduced in size, and the semiconductor module 2 is consequently reduced in size.

A positive electrode terminal is bonded to the first bonding area 22a8 of the first terminal 22, and a negative electrode terminal is bonded to the second bonding area 23a8 of the second terminal 23. In this way, the energization direction in the first terminal 22 and the energization direction in the second terminal 23 are opposite to each other. In this way, the inductance is canceled out, and as a result, an inductance reduction effect is obtained. Here, since it is possible to shorten the length in the thickness direction between the first terminal 22 and the second terminal 23, the inductance reduction effect is further enhanced, and the inductance between the first terminal 22 and the second terminal 23 is consequently reduced further.

Next, modification 1-1 according to the first embodiment will be described. In the first embodiment, the first conductive plate 22a and the second conductive plate 23a are immersed in the solution 51 containing aluminum, a coating layer is attached to the surfaces of the first conductive plate 22a and the second conductive plate 23a, and the individual coating film is oxidized by an anodic oxidation method. In modification 1-1, a clad material is used for first conductive plates 22a and second conductive plates 23a. A semiconductor module 2 according to modification 1-1 includes terminal stack portions 24 for which a clad material is used. The semiconductor module 2 according to modification 1-1 is the same as that according to the first embodiment, except for the terminal stack portions 24.

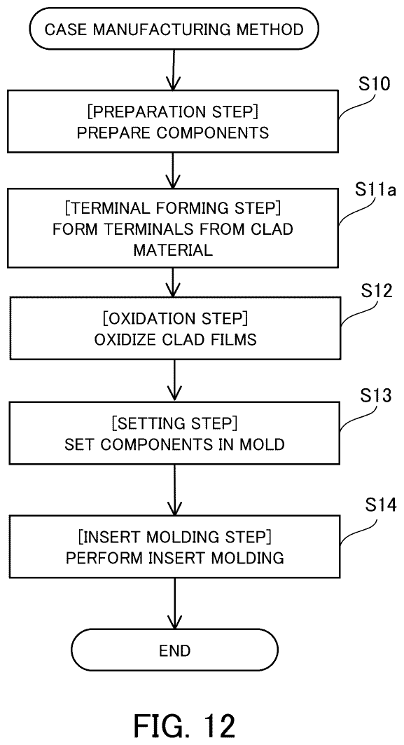

A method of manufacturing the case 20 included in the semiconductor module 2 according to modification 1-1 will be described with reference to FIG. 12. FIG. 12 is a flowchart illustrating a method of manufacturing the case included in the semiconductor module according to modification 1-1 of the first embodiment. The method of manufacturing the case 20 illustrated in FIG. 12 is included in the method of manufacturing the semiconductor module 2. The description of the same steps as those in the flowchart of FIG. 9 will be simplified.

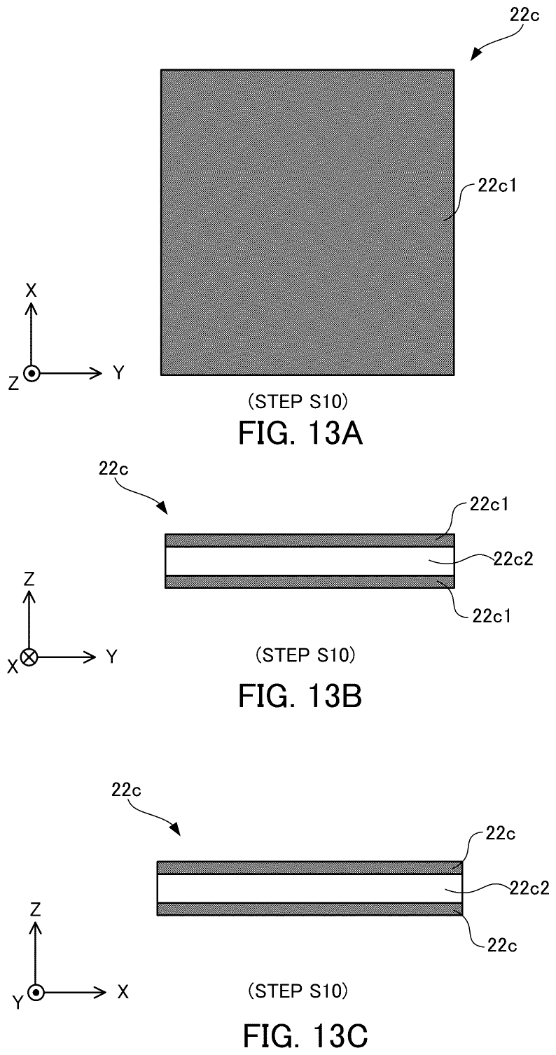

First, as in the flowchart of FIG. 9, a preparation step of preparing components for manufacturing the case 20 is performed (step S10). In this step, a clad material is prepared as a material of various terminals. The clad material will be described with reference to FIGS. 13A to 13C. FIGS. 13A to 13C are diagrams illustrating a preparation step included in the case manufacturing method according to modification 1-1 of the first embodiment. FIG. 13A is a plan view of a clad material 22c, FIG. 13B is a side view of the clad material 22c seen in the ±X direction, and FIG. 13C is a side view of the clad material 22c seen in the −Y direction.

The clad material 22c includes a conductive plate 22c2 and a clad film 22cl formed on each of the front surface and the rear surface of the conductive plate 22c2. The conductive plate 22c2 is the base material of the clad material 22c, and is made of copper or an alloy containing copper as a main component, as is the case with the individual first conductive plate 22a according to the first embodiment. The clad film 22cl is mainly made of aluminum. The clad material 22c is formed by providing a clad film 22cl on the front surface and the rear surface of a conductive plate 22c2 and rolling the conductive plate 22c2 under pressure. When the clad film 22cl is pressure-bonded to the conductive plate 22c2 in this manner, the metal of the conductive plate 22c2 and the metal of the clad film 22cl are bonded to each other without using a bonding material by rolling bonding in which the metal of the conductive plate 22c2 and the metal of the clad film 22cl are interatomically bonded by pressure. Therefore, the clad film 22cl is hardly peeled off from the conductive plate 22c2.

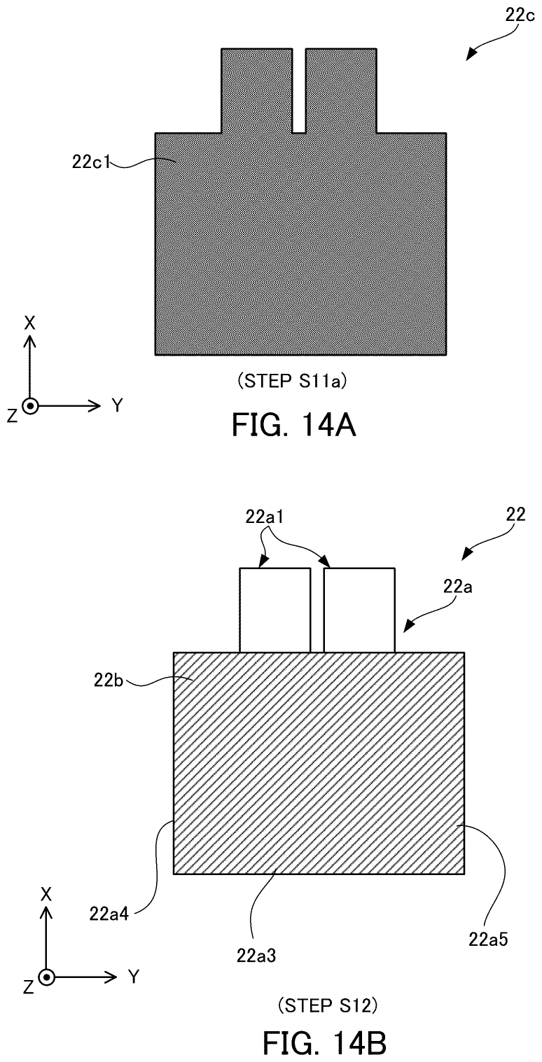

Next, a terminal forming step of forming terminals from the clad material 22c is performed (step S11a). The terminal forming step will be described with reference to FIGS. 14A and 14B. FIGS. 14A and 14B are diagrams illustrating a terminal forming step and an oxidation step, respectively, included in the case manufacturing method according to modification 1-1 of the first embodiment. FIG. 14A is a plan view illustrating a state after the terminal forming step. FIG. 14B is a plan view illustrating a state after the oxidation step described later.

The clad material 22c prepared in step S10 is subjected to press working (shearing) such that the shapes of the first conductive plate 22a and the second conductive plate 23a according to the first embodiment are obtained. After the press working, the clad material 22c having a shape as illustrated in FIG. 14A is obtained. Although not illustrated in FIG. 14A, the clad film 22cl is formed on each of the front surface and the rear surface of the first conductive plate 22a. Further, although not illustrated, a clad film is also formed on each of the front surface and the rear surface of the second conductive plate 23a.

Next, an oxidation step of oxidizing the clad film 22cl of the first conductive plate 22a is performed (step S12). In order to oxidize the clad films 22cl provided on the first conductive plate 22a and the second conductive plate 23a formed in step S11a, an anodic oxidation method is performed as in the first embodiment. As a result, the clad films 22cl on the front surface and the rear surface of the first conductive plate 22a are oxidized to be the first oxide film 22b, and the first terminal 22 according to modification 1-1 is obtained.

In the case of the first terminal 22, the first oxide film 22b is also formed on the front surface and the rear surface of the first connection portions 22al. The first oxide film 22b on the first connection portions 22al may be removed. By the removal, the first terminal 22 illustrated in FIG. 14B is obtained. Although not illustrated, the second terminals 23 are also obtained in the same manner.

In this example, the clad material 22c is prepared in the preparation step of step S10, and the terminal forming step of step S11a and the oxidation step of step S12 are performed on the clad material 22c. However, the embodiment is not limited to this example. The first terminals 22 may be prepared in the preparation step of step S10 by performing the terminal forming step and the oxidation step on the clad material 22c. The same applies to the second terminals 23.

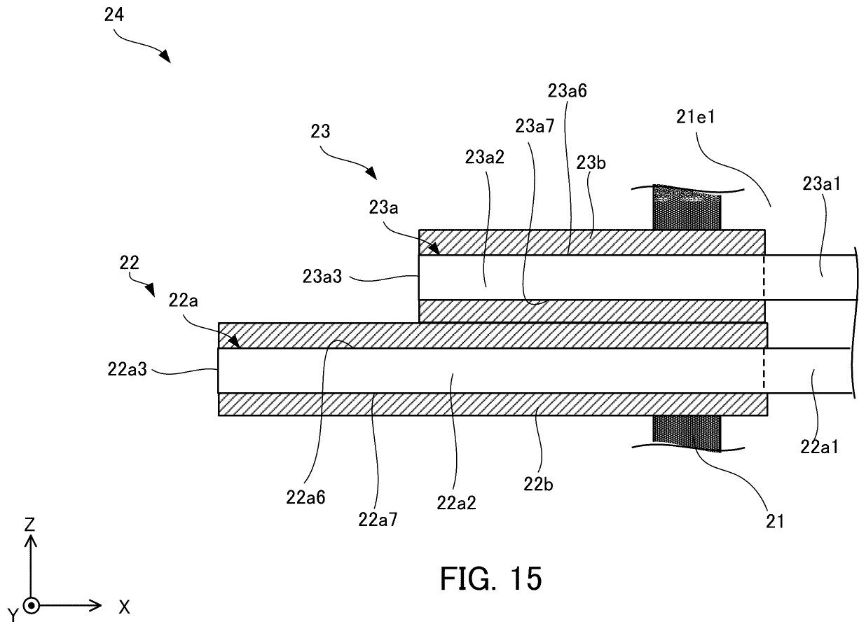

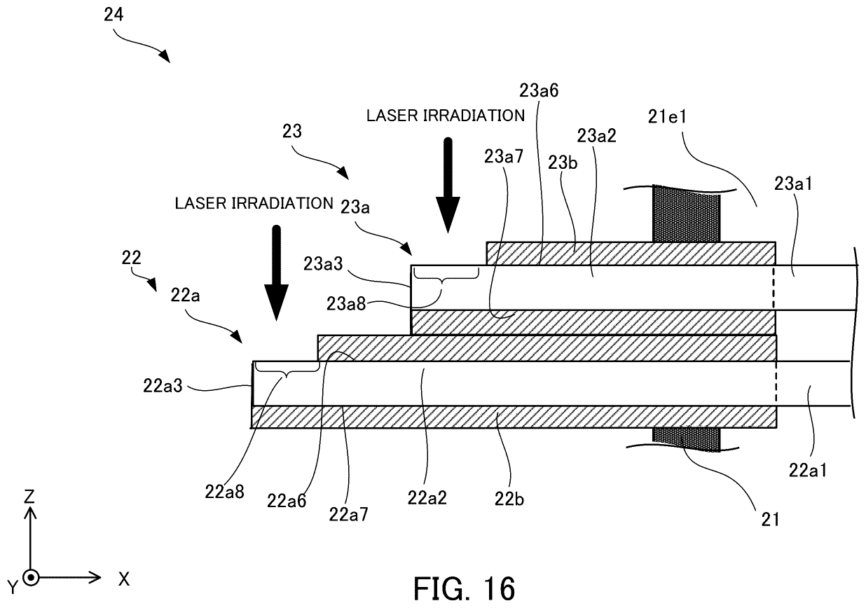

When the first terminals 22 and the second terminals 23 are obtained as described above, in subsequent steps S13 and S14, the same processes as those in steps S13 and S14 in FIG. 9 according to the first embodiment are performed, and the case 20 is consequently obtained. The semiconductor module 2 including the case 20 manufactured as described above will be described with reference to FIGS. 15 and 16. FIG. 15 is a cross-sectional view of the terminal stack portion according to modification 1-1 of the first embodiment, and FIG. 16 is a cross-sectional view of the terminal stack portion according to modification 1-1 of the first embodiment from which the bonding areas are removed. FIGS. 15 and 16 correspond to FIGS. 7 and 8 according to the first embodiment, respectively.

As illustrated in FIG. 15, the terminal stack portion 24 according to modification 1-1 also includes the first terminal 22 and the second terminal 23. The terminal stack portion 24 according to modification 1-1 also includes the first terminal 22 having a flat plate shape and the second terminal 23 having a flat plate shape stacked on the first terminal 22. The front end surface 22a3 included in the first terminal 22 extends further outward (in the −X direction) beyond the front end surface 23a3 included in the second terminal 23, and the first bonding area 22a8 included in the first terminal 22 is exposed. The terminal stack portion 24 is fixed to the frame portion 21 such that the front end surface 22a3 of the first terminal 22 is flush with the first side portion 21a of the frame portion 21.

The individual first terminal 22 includes a first conductive plate 22a and a first oxide film 22b as in the case of FIG. 7 according to the first embodiment. As described above, the first terminal 22 is obtained from the clad material 22c. Therefore, the first oxide film 22b is formed only on the first front surface 22a6 and the first rear surface 22a7 of the first wiring portion 22a2 of the first conductive plate 22a. The first oxide film 22b is not formed on the front end surface 22a3, the rear end surface (the reference character thereof is omitted), and the first side surfaces 22a4 and 22a5 of the individual first wiring portion 22a2 of the first conductive plate 22a.

The second terminal 23 also includes a second conductive plate 23a and a second oxide film 23b as in the case of FIG. 7 according to the first embodiment. The individual second terminal 23 is also obtained from the clad material as described above. Therefore, the second oxide film 23b is formed only on the second front surface 23a6 and the second rear surface 23a7 of the second wiring portion 23a2 of the second conductive plate 23a. The second oxide film 23b is not formed on the front end surface 23a3, the rear end surface (the reference character thereof is omitted), and the second side surfaces 23a4 and 23a5 of the individual second wiring portion 23a2 of the second conductive plate 23a.

As described above, the first oxide film 22b is not formed on the front end surface 22a3, the first side surfaces 22a4 and 22a5, and the rear end surface of the first conductive plate 22a of the first terminal 22. In addition, and the second oxide film 23b is not formed on the front end surface 23a3, the second side surfaces 23a4 and 23a5, and the rear end surface of the second conductive plate 23a of the second terminal 23. For this reason, in order to maintain the insulation between the first terminal 22 and the second terminal 23, it is desirable that the creepage distance between the front end surfaces 22a3 and 23a3, the creepage distance between the first side surfaces 22a4 and 22a5 and the second side surfaces 23a4 and 23a5, and the creepage distance between the rear end surfaces be set to be longer than those in the case of FIG. 7 according to the first embodiment in plan view. For example, the front end surface 22a3 of the first terminal 22 may be formed to extend more in the −X direction from the front end surface 23a3 of the second terminal 23 as compared with the case of FIG. 7 according to the first embodiment. Further, the first side surfaces 22a4 and 22a5 may be formed to extend more in the ±Y directions from the second side surfaces 23a4 and 23a5, respectively, as compared with the case according to the first embodiment.

In addition, a first connection terminal 43 and a coupling member 41, which will be described later, are also bonded to the first terminal 22 and the second terminal 23 of the terminal stack portion 24 according to modification 1-1, respectively (see FIG. 19, which will be described later). At this time, the first oxide film 22b on the first bonding area 22a8 of the first terminal 22 is also subjected to laser irradiation as in the first embodiment. In this process, for example, an area of the first oxide film 22b of the first terminal 22, the area having a predetermined length in the ±X direction from the front end surface 22a3 and extending from the first side surface 22a4 to the first side surface 22a5 in plan view, may be removed by laser irradiation.

Similarly, laser irradiation is performed on the second oxide film 23b on the second bonding area 23a8 of the second terminal 23. In this process, for example, an area of the second oxide film 23b of the second terminal 23, the area having a predetermined length in the ±X direction from the front end surface 23a3 and extending from the second side surface 23a4 to the second side surface 23a5 in plan view, may be removed by laser irradiation.

As a result, as illustrated in FIG. 16, the first oxide film 22b near the front end surface 22a3 is removed, and the first bonding area 22a8 of the first conductive plate 22a is exposed. The second oxide film 23b near the front end surface 23a3 is removed, and the second bonding area 23a8 of the second conductive plate 23a is exposed. The areas of the first oxide film 22b and the second oxide film 23b, the areas to be removed by laser irradiation, are merely examples. The areas illustrated in FIG. 8 may be alternatively removed. Further, in order to remove the first oxide film 22b and the second oxide film 23b, other than the laser irradiation, polishing with a file or cutting with a milling cutter may be performed as in the first embodiment.

### Second Embodiment

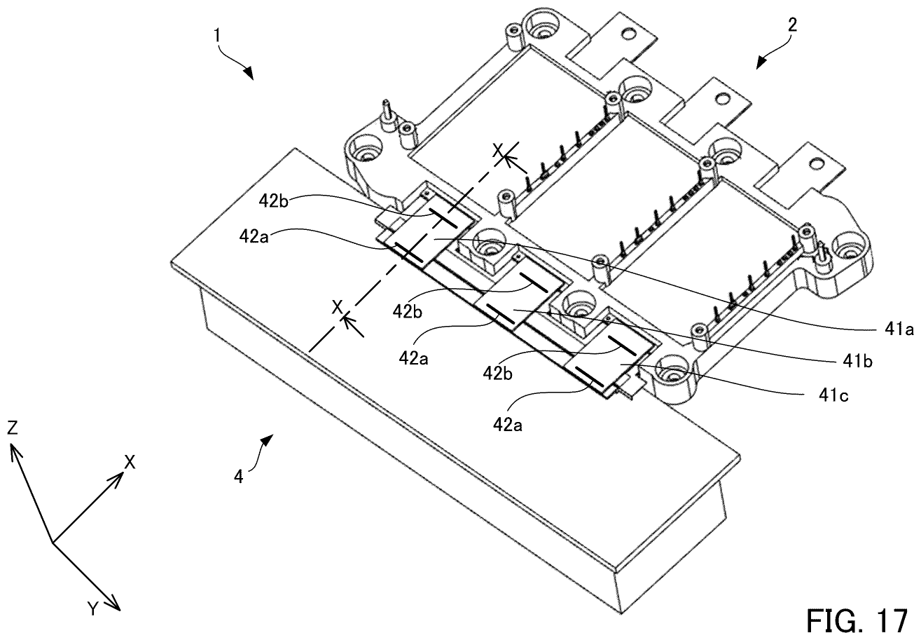

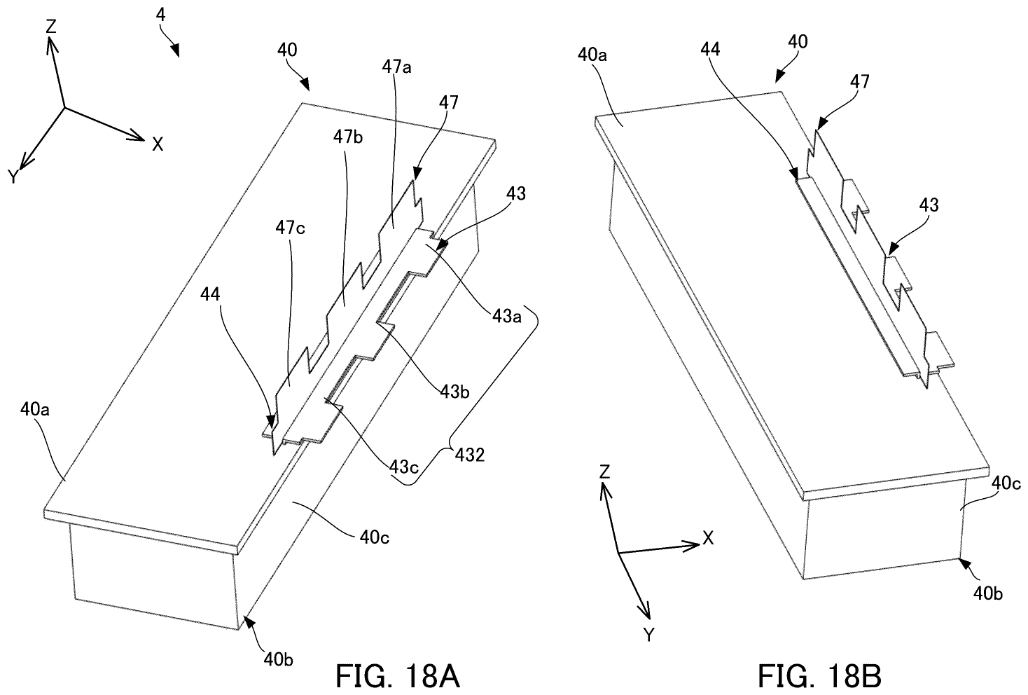

Next, a second embodiment will be described with reference to FIGS. 17, 18A, and 18B. FIG. 17 is a perspective view of a semiconductor device according to the second embodiment, and FIGS. 18A and 18B are perspective views of a capacitor according to the second embodiment. FIG. 18A is a perspective view of the capacitor 4, and FIG. 18B is a perspective view of the capacitor 4 from a direction opposite to FIG. 18A. In the second embodiment, a semiconductor device 1 includes the semiconductor module 2 according to the first embodiment, and the semiconductor module 2 according to the first embodiment and the capacitor 4 are connected to each other. In the second embodiment, the same components as those of the semiconductor module 2 according to the first embodiment are denoted by the same reference characters, and the description thereof will be simplified or omitted.

The following description will be made on an example in which the first bonding area 22a8 of the first terminal 22 and the second bonding area 23a8 of the second terminal 23 illustrated in FIG. 8 according to the first embodiment are not exposed to the outside.

As illustrated in FIG. 17, the semiconductor device 1 according to the second embodiment includes a semiconductor module 2 and a capacitor 4. In this case, the semiconductor module 2 and the capacitor 4 are disposed as close to each other as possible, and their side portions face each other. Coupling members 41a, 41b, and 41c, each of which is an example of a fourth conductive plate (or coupling plate), electrically connect and mechanically couple the semiconductor module 2 and the capacitor 4. In this case, each of the coupling members 41a, 41b, and 41c has a linear laser weld mark 42a on its portion in the direction of the capacitor 4 and has a linear laser weld mark 42b on its portion in the direction of the semiconductor module 2. The number and width of the coupling members 41a, 41b, and 41c are merely examples. The number and width of the coupling members 41a, 41b, and 41c are selected in accordance with the number and width of the terminal stack portions 24 included in the semiconductor module 2. Hereinafter, the coupling members 41a, 41b, and 41c will be described as the coupling member 41 as needed when they are not particularly distinguished from each other.

As illustrated in FIGS. 18A and 18B, the capacitor 4 includes a case 40, a first connection terminal 43, an insulating sheet 47, and a second connection terminal 44. The case 40 is a capacitor body. The case 40 includes a lid portion 40a and a storage case 40b, and the first connection terminal 43, the insulating sheet 47, and the second connection terminal 44 are disposed on the lid portion 40a. A plurality of capacitor elements each having an N pole and a P pole are stored in the storage case 40b. The material of a lid portion 40a and the storage case 40b is, for example, epoxy resin. One end portion of the first connection terminal 43 is electrically connected to the N-poles of all the capacitor elements in the case 40. The other end portion of the first connection terminal 43 extends outward toward a first side surface 40c of the case 40. A portion of the first connection terminal 43, the portion extending from the case 40, has an approximately L-shape in a side view (see FIGS. 18A and 18B). As will be described later with reference to FIG. 19, the approximately L-shaped first connection terminal 43 includes a first connection conduction portion 431 and a first connection wiring portion 432. One end portion of the first connection conduction portion 431 is electrically connected to the N poles of all the capacitor elements in the case 40, and extends vertically to the outside from the front surface of the lid portion 40a of the case 40. The first connection wiring portion 432 is approximately orthogonal to the first connection conduction portion 431 and extends toward the first side surface 40c approximately in parallel to the front surface of the lid portion 40a of the case 40. In addition, a portion (first connection wiring portion 432) of the first connection terminal 43, the portion extending from the lid portion 40a of the case 40, is divided into a first connection portion 43a, a second connection portion 43b, and a third connection portion 43c to form a comb shape in plan view. In FIG. 18B, the reference characters of the first connection portion 43a, the second connection portion 43b, and the third connection portion 43c are omitted. The widths of the first connection portion 43a, the second connection portion 43b, and the third connection portion 43c correspond to the widths of the storage areas 21e1, 21e2, and 21e3 (first terminals 22) of the semiconductor module 2, respectively. The first connection terminal 43 is made of a metal having excellent electric conductivity. The metal is, for example, copper or an alloy containing copper as a main component.

One end portion of the second connection terminal 44 is electrically connected to the P poles of all the capacitor elements in the case 40. The other end portion of the second connection terminal 44 extends to the outside from the front surface of the lid portion 40a of the case 40. The second connection terminal 44 is provided away from the first connection terminal 43 in the opposite direction of the first side surface 40c. A portion of the second connection terminal 44, the portion extending from the case 40, has an approximately L-shape in a side view (see FIGS. 18A and 18B). As will be described later with reference to FIG. 19, the approximately L-shaped second connection terminal 44 includes a second connection conduction portion 441 and a second connection wiring portion 442. One end portion of the second conductive connection portion 441 is electrically connected to the P electrodes of the capacitor elements in the case 40, and extends vertically to the outside from the front surface of the case 40. The second connection wiring portion 442 is approximately orthogonal to the second connection conduction portion 441 and extends in the opposite direction of the first side surface 40c approximately in parallel to the front surface of the case 40. The second connection terminal 44 is made of a metal having excellent electric conductivity. The metal is, for example, copper or an alloy containing copper as a main component.

The insulating sheet 47 is longer than the first connection terminal 43 and extends outward between the first connection terminal 43 and the second connection terminal 44 of the case 40. Therefore, the insulation between the first connection terminal 43 and the second connection terminal 44 is maintained by the insulating sheet 47 outside the case 40. The insulating sheet 47 is made of an insulating material having flexibility and insulating properties. As the insulating material, for example, an insulating paper made of a wholly aromatic polyamide polymer or a sheet-like material formed of a fluorine-based or polyimide-based resin material is used.

Further, the front end portion of the insulating sheet 47 is divided into a first attachment portion 47a, a second attachment portion 47b, and a third attachment portion 47c to form a comb teeth shape in plan view. In FIG. 18B, the reference characters of the first attachment portion 47a, the second attachment portion 47b, and the third attachment portion 47c are omitted. The widths of the first attachment portion 47a, the second attachment portion 47b, and the third attachment portion 47c correspond to the widths of the storage areas 21e1, 21e2, and 21e3 of the semiconductor module 2, respectively.

Next, the coupling members 41a, 41b, and 41c will be described (see FIG. 17). The coupling members 41a, 41b, and 41c have a flat plate shape in plan view. The width of one end portion of each of the coupling members 41a, 41b, and 41c corresponds to the width of a corresponding one of the storage areas 21e1, 21e2, and 21e3 (second terminals 23) of the semiconductor modules 2. The thickness of the coupling members 41a, 41b, and 41c is formed to be thinner than the thickness of the second terminals 23. One end portion of each of the coupling members 41a, 41b, and 41c is bonded to the second bonding area 23a8 on a corresponding one of the second front surfaces 23a6 of the second terminals 23 of the semiconductor module 2 by laser welding. The other end of each of the coupling members 41a, 41b, and 41c is bonded to the second connection terminal 44 of the capacitor 4 by laser welding. The bonding by laser welding may be performed using either a seam laser that continuously emits a laser beam or a spot laser that emits a pulsed laser beam. FIG. 17 illustrates a case where the bonding is performed by a seam laser. Therefore, on each of the coupling members 41a, 41b, and 41c in FIG. 17, a linear laser weld mark 42a is illustrated in the direction of the capacitor 4, and a linear laser weld mark 42b is illustrated in the direction of the semiconductor module 2. Details of the bonding of the coupling members 41a, 41b, and 41c will be described later.

The coupling members 41a, 41b, and 41c are made of a metal having excellent electric conductivity. The metal is, for example, copper or an alloy containing copper as a main component. According to the second embodiment, each of the three coupling members 41a, 41b, and 41c is bonded to a corresponding one of the three second terminals 23. However, the present embodiment is not limited to this example. A flat plate-shaped coupling member having an end portion in the direction of the semiconductor module 2 may be used, and this end portion may have a comb teeth shape, as in the first connection terminal 43 and the insulating sheet 47, such that the teeth portions correspond to the second terminals 23.

Next, a connection mechanism between the semiconductor module 2 of the semiconductor device 1 and the capacitor 4 will be described with reference to FIG. 19. FIG. 19 is a cross-sectional view of the capacitor and the semiconductor module included in the semiconductor device according to the second embodiment. FIG. 19 is a cross-sectional view taken along an alternate long and short dash line X-X illustrated in FIG. 17. In FIG. 19, the cross sections of the other coupling members 41b and 41c of the semiconductor device 1 in FIG. 17 have the same configuration.

In the semiconductor device 1, the first connection wiring portion 432 of the first connection terminal 43 of the capacitor 4 is bonded at a first bonding portion 221 in the first bonding area 22a8 of the first front surface 22a6 of the first terminal 22 of the semiconductor module 2. In addition, the coupling member 41 bonded to the second connection wiring portion 442 of the second connection terminal 44 of the capacitor 4 at a third bonding portion 443 is bonded at a second bonding portion 231 in the second bonding area 23a8 of the second front surface 23a6 of the second terminal 23 of the semiconductor module 2. The second bonding portion 231 and the third bonding portion 443 include the laser weld marks 42b and 42a, respectively, formed in the coupling member 41. Similarly, the first bonding portion 221 includes a laser weld mark (not illustrated) formed on the first connection wiring portion 432 of the first connection terminal 43.

That is, although not illustrated, the first connection portion 43a, the second connection portion 43b, and the third connection portion 43c of the first connection wiring portion 432 of the first connection terminal 43 of the capacitor 4 are bonded to the first terminals 22 of the semiconductor module 2 at their respective first bonding portions 221. In addition, the second connection wiring portion 442 of the second connection terminal 44 of the capacitor 4 is bonded to the coupling members 41 at their respective third bonding portions 443. The second terminals 23 of the semiconductor module 2 are bonded to the coupling members 41 at their respective second bonding portions 231. As illustrated in FIG. 8, this bonding may be performed on the first bonding area 22a8 and the second bonding area 23a8 in which the first conductive plate 22a and the second conductive plate 23a are exposed to the outside from the opening portions of the first oxide film 22b and the second oxide film 23b by, for example, irradiating the first oxide film 22b of the first terminal 22 and the second oxide film 23b of the second terminal 23 with a laser in advance. In this case, the first bonding portion 221 passes through the opening portion of the first oxide film 22b, and the second bonding portion 231 passes through the opening portion of the second oxide film 23b.

However, according to the second embodiment, the first bonding area 22a8 of the first terminal 22 and the second bonding area 23a8 of the second terminal 23 are not exposed to the outside as illustrated in FIG. 7. In this case, for example, when the laser weld mark formed by irradiating the first connection wiring portion 432 of the first connection terminal 43 of the capacitor 4 with a laser when the first connection wiring portion 432 is bonded to the first terminal 22 passes through the first connection wiring portion 432 of the first connection terminal 43 and the first oxide film 22b and reaches the first conductive plate 22a, the first bonding area 22a8 in the first oxide film 22b does not need to be removed in advance. Similarly, the second bonding area 23a8 in the second oxide film 23b does not need to be removed in advance.

Each first bonding portion 221 is a portion where a first terminal 22 of the semiconductor module 2 and a first connection terminal 43 of the capacitor 4 are bonded by the above-described laser welding. The first connection terminal 43 of the capacitor 4 is disposed on the first terminal 22, and a laser beam is emitted from above the first connection terminal 43 to the first connection terminal 43. The laser beam melts the first connection terminal 43 downward (−Z direction) from the front surface thereof, and further melts the first oxide film 22b and the first conductive plate 22a of the first terminal 22. As a result, a laser weld mark is formed at the melted portion of the front surface of the first connection wiring portion 432 of the first connection terminal 43. However, the laser beam melts the first conductive plate 22a to such an extent that does not penetrate the first conductive plate 22a. The first bonding portion 221 generated by solidification of the melted portion extends from the front surface of the first connection terminal 43 to the middle of the first terminal 22 (the first conductive plate 22a). In this way, the first terminal 22 of the semiconductor module 2 and the first connection terminal 43 of the capacitor 4 are bonded to each other by the first bonding portion 221.

The insulating sheet 47 of the capacitor 4 covers the first connection terminal 43 from above and is bent toward the semiconductor module 2. In this case, a portion of the insulating sheet 47 extending from the capacitor 4 to the outside is longer than the first connection terminal 43. The front end portion of the insulating sheet 47 extends beyond the upper portion of the first connection terminal 43 so as to extend along a terrace portion 222, which is a portion of the first terminal 22 of the semiconductor module 2 and which does not overlap the stacked second terminal 23. The terrace portion 222 extends from the second bonding portion 231 toward the first bonding portion 221 in plan view. The front end portion of the insulating sheet 47 extends to a location a little before the front end surface of the second terminal 23. That is, the ±Z direction gap between the front end portion of the insulating sheet 47 and the coupling member 41 is larger than the ±Z direction gap between the terrace portion 222 and the insulating sheet 47. In addition, the distance from the front end surface of the first connection terminal 43 to the front end surface of the second terminal 23 is 6 mm or more and 12.5 mm or less. Although not illustrated in the drawings, the first attachment portion 47a, the second attachment portion 47b, and the third attachment portion 47c of the front end portion of the insulating sheet 47 extend over the first terminals 22 of the semiconductor module 2.

Each second bonding portion 231 is a portion where a second terminal 23 of the semiconductor module 2 and a coupling member 41 of the capacitor 4 are bonded to each other by laser welding, as in the first bonding portions 221. In this case, a laser weld mark 42b is formed at the melted portion of the front surface of the individual coupling member 41. The coupling member 41 is disposed on the second terminal 23, and a laser beam is emitted from above the coupling member 41 to the coupling member 41. The laser beam melts the coupling member 41 downward (−Z direction) from the front surface thereof, and further melts the second oxide film 23b and the second conductive plate 23a of the second terminal 23. At this time, a laser weld mark 42b is formed at the melted portion of the front surface of the coupling member 41. However, the laser beam melts the second conductive plate 23a to such an extent that does not penetrate the second conductive plate 23a. The second bonding portion 231 generated by solidification of the melted portion extends from the front surface of the coupling member 41 to the middle of the second terminal 23 (the second conductive plate 23a). In this way, the second terminal 23 of the semiconductor module 2 and the coupling member 41 are bonded by the second bonding portion 231.

The front surface of the second connection wiring portion 442 of the second connection terminal 44 of the capacitor 4 is flush with the front surface of the second terminal 23 of the semiconductor module 2. The other end portion of the coupling member 41 is bonded to the second connection wiring portion 442 of the second connection terminal 44 of the capacitor 4 at the third bonding portion 443, and one end portion of the coupling member 41 is bonded to the second terminal 23 of the semiconductor module 2 at the second bonding portion 231. In this case, the second bonding portion 231 and the third bonding portion 443 are disposed parallel to the first bonding portion 221.

Although not illustrated, one end portion of each of the coupling members 41a, 41b, and 41c is bonded to a corresponding one of the second bonding portions 231 of the second terminals 23 of the semiconductor module 2. Thus, the coupling members 41 electrically connect the second connection terminal 44 of the capacitor 4 and the second terminals 23 of the semiconductor module 2. A gap is formed between the rear surface of the individual coupling member 41 and the front surface of the individual first connection wiring portion 432 of the first connection terminal 43 of the capacitor 4. The insulating sheet 47 is provided in this gap. Therefore, the first connection terminal 43 maintains insulation from the coupling member 41 and the second connection terminal 44. The insulating sheet 47 is not limited to the shape illustrated in FIG. 19, and may be in contact with the rear surface of the coupling member 41, the front surface of the first connection terminal 43, and the front end portion of the second terminal 23 in the gap.

In the semiconductor module 2 included in the semiconductor device 1 according to the second embodiment, as described above, the first oxide film 22b and the second oxide film 23b are used as the insulating members between the first wiring portion 22a2 of the individual first conductive plate 22a and the second wiring portion 23a2 of the individual second conductive plate 23a. As a result, the same effect as that according to the first embodiment is obtained. The first terminals 22 and the second terminals 23 of the semiconductor module 2 are bonded to the first connection terminal 43 of the capacitor 4 and the coupling members 41 by laser welding. In this case, by melting the first oxide film 22b of the individual first terminal 22 and the second oxide film 23b of the individual second terminal 23 with a laser beam, the first wiring portion 22a2 of the individual first terminal 22 and the second wiring portion 23a2 of the individual second terminal 23 of the semiconductor module 2 are bonded to the first connection terminal 43 of the capacitor 4 and the coupling members 41. Therefore, it is possible to omit the step of forming the openings in the first oxide film 22b of the first terminal 22 and the second oxide film 23b of the second terminal 23.

The second embodiment is described based on an example in which the individual first terminal 22 and the individual second terminal 23 of the semiconductor module 2 according to the first embodiment illustrated in FIG. 7 are bonded to the first connection terminal 43 and the coupling members 41 of the capacitor 4 by laser welding. The present embodiment is not limited to this example. Alternatively, the individual first terminal 22 and the individual second terminal 23 of the semiconductor module 2 according to the modification of the first embodiment illustrated in FIG. 15 may be bonded to the first connection terminal 43 and the coupling members 41 of the capacitor 4 by laser welding.

As in the case of FIG. 8, as illustrated in FIG. 16, the first bonding area 22a8 and the second bonding area 23a8 of the individual first terminal 22 and the individual second terminal 23 of the semiconductor module 2 according to the modification of the first embodiment, the first bonding area 22a8 and the second bonding area 23a8 having been opened in advance, may alternatively be bonded to the first connection terminal 43 and the coupling members 41 of the capacitor 4 by laser welding in the same manner.

### Third Embodiment

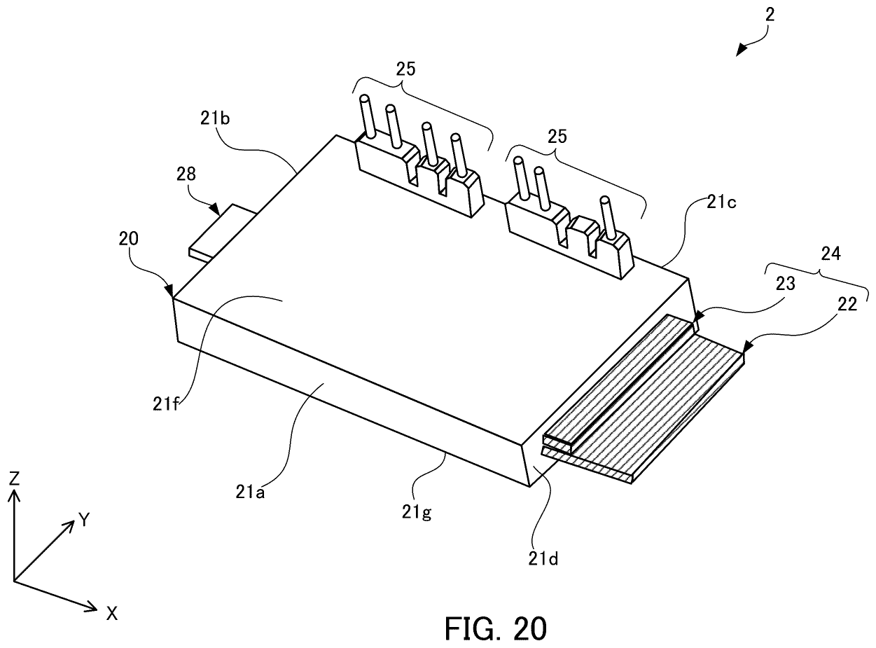

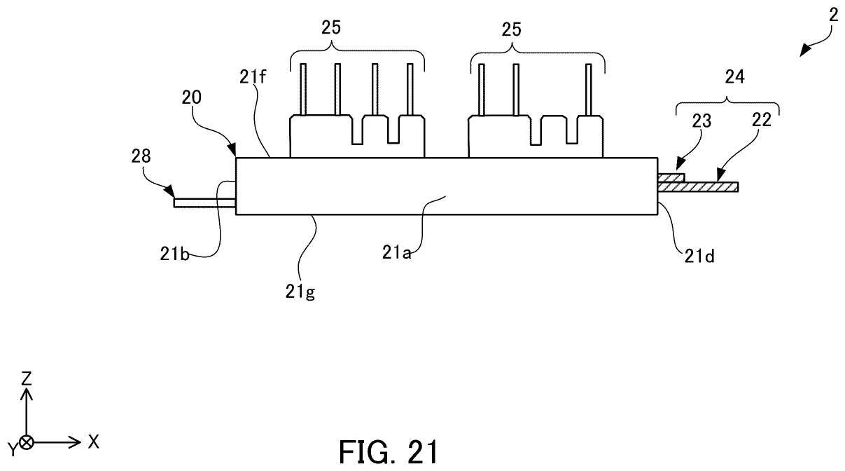

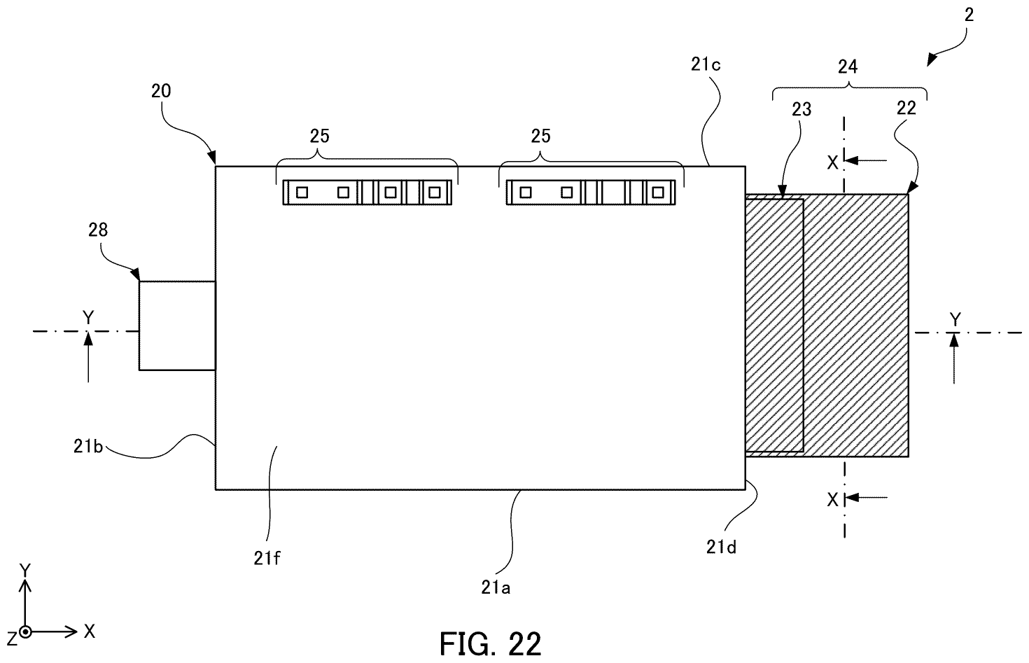

A semiconductor module 2 according to a third embodiment will be described with reference to FIGS. 20 to 22. FIG. 20 is a perspective view of the semiconductor module according to the third embodiment, FIG. 21 is a cross-sectional view of the semiconductor module according to the third embodiment, and FIG. 22 is a plan view of the semiconductor module according to the third embodiment. FIG. 21 is a side view of a semiconductor device 1 in FIG. 20 as viewed in the ±Y direction. FIG. 22 is a plan view of the semiconductor module 2 of FIG. 20 as viewed in the −Z direction.

The semiconductor module 2 may include at least a case 20, an output terminal 28, control terminals 25, and a terminal stack portion 24. The case 20 seals an insulated circuit substrate and semiconductor chips (not illustrated). The case 20 may be made of, for example, a thermosetting resin as a main component. Examples of the thermosetting resin include an epoxy resin, a phenol resin, a maleimide resin, and a polyester resin. A filler may be further added to the thermosetting resin. The filler may be, for example, ceramics. Ceramics have insulating properties and high thermal conductivity. Made of a thermosetting resin, the case 20 is formed as a cubic shape, for example. The case 20 includes a first side portion 21a, a second side portion 21b, a third side portion 21c, a fourth side portion 21d, a top surface 21f, and a bottom surface 21g. The case 20 may be substantially cuboid, and may have chamfered or rounded corners. The top surface 21f and the bottom surface 21g have a rectangular shape in plan view. The first side portion 21a, the second side portion 21b, the third side portion 21c, and the fourth side portion 21d sequentially surround four sides of the top surface 21f and the bottom surface 21g in plan view. The first side portion 21a and the third side portion 21c are parallel to the longitudinal direction (±Y directions) (corresponding to the long sides of the case 20), and the second side portion 21b and the fourth side portion 21d are parallel to the lateral direction (±X directions) of the case 20 (corresponding to the short sides).

The insulated circuit substrate includes an insulating plate, a metal plate formed on the rear surface of the insulating plate, and a plurality of wiring plates formed on the front surface of the insulating plate. The insulating plate, the plurality of wiring plates, and the metal plate are made of the same materials as those of the insulating plate 31, the wiring plates 32a to 32i, and the metal plate 33 according to the first embodiment. The plurality of wiring plates may include wiring plates capable of realizing the function of the semiconductor module 2 according to the third embodiment. The output terminal 28 and the control terminals 25, which will be described later, are connected to predetermined wiring plates among the plurality of wiring plates.

The semiconductor chips are the same as the semiconductor chips 34a to 34d according to the first embodiment. The semiconductor chips are disposed on the wiring plates of the insulated circuit substrate via a bonding member. The output terminal 28 is electrically connected to predetermined conductive patterns of the insulated circuit substrate in the case 20, and extends from the second side portion 21b of the case 20 to the outside. In this case, the output terminal 28 extends to the outside perpendicularly (−X direction) to the second side portion 21b. The predetermined conductive patterns are electrically connected to the output electrodes of the semiconductor chips. At least a portion of the output terminal 28, the portion extending outward from the second side portion 21b of the case 20, has a flat plate shape. A through hole may be formed in this outwardly extending portion of the output terminal 28. The output terminal 28 is made of a metal having excellent electric conductivity. The metal is, for example, copper, aluminum, or an alloy containing at least one of these metals as a main component. The surface of the output terminal 28 may be plated to improve corrosion resistance. In this case, the plating material used is, for example, nickel, a nickel-phosphorus alloy, or a nickel-boron alloy.

The control terminals 25 are electrically connected to predetermined conductive patterns of the insulated circuit substrate in the case 20, and extend from the top surface 21f of the case 20 to the outside perpendicularly (+Z direction) to the top surface 21f. The predetermined conductive patterns are electrically connected to the control electrodes of the semiconductor chips. The predetermined conductive patterns may be electrically connected to the output electrodes of the semiconductor chips. In this case, a sense current flowing through the semiconductor chips flows through the control terminals 25 electrically connected to the predetermined conductive patterns.

A plurality of control terminals 25 may be provided on the top surface 21f along and on the third side portion 21c. A portion of each of the control terminals 25, the portion being located near the top surface 21f, may be protected by a protection portion. The protective portion in this case may be made of the same material as the case 20.

The terminal stack portion 24 is electrically connected to predetermined conductive patterns of the insulated circuit substrate in the case 20, and extends from the fourth side portion 21d of the case 20 to the outside. The terminal stack portion 24 extends to the outside perpendicularly (±X direction) to the fourth side portion 21d. An external positive electrode and an external negative electrode are connected to the terminal stack portion 24. The predetermined conductive patterns are electrically connected to the output electrodes and the input electrodes of the semiconductor chips.

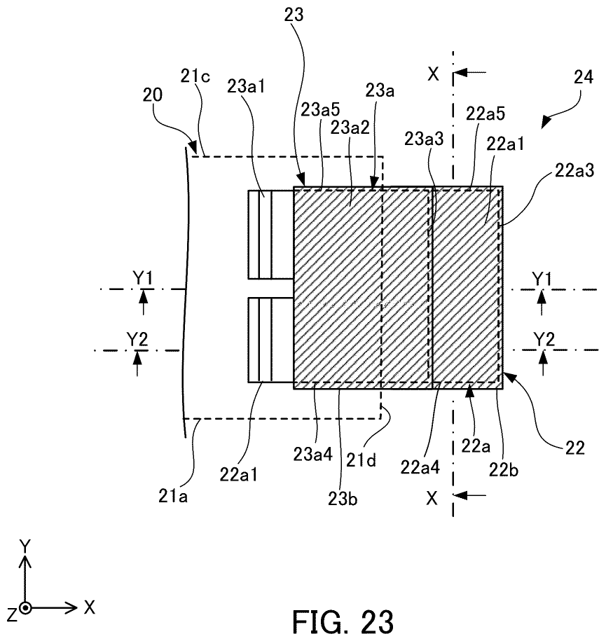

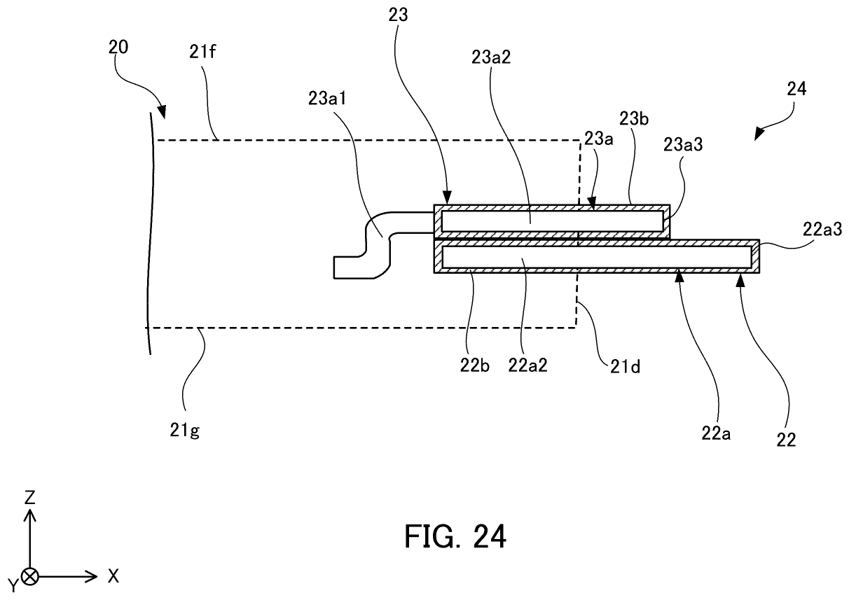

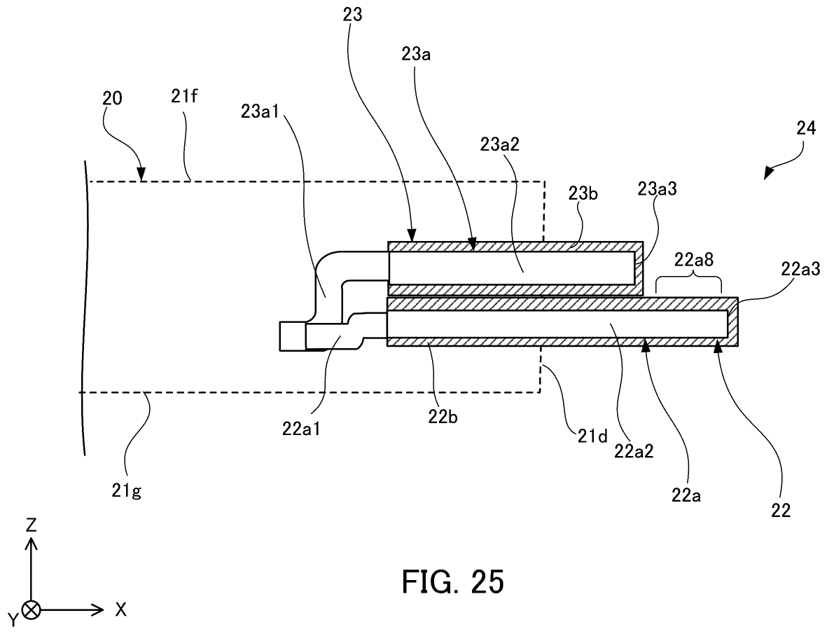

Details of the terminal stack portion 24 will be described with reference to FIGS. 23 to 25. FIG. 23 is a plan view of a first terminal and a second terminal according to the third embodiment, FIG. 24 is a cross-sectional view of the first terminal and the second terminal according to the third embodiment, and FIG. 25 is another cross-sectional view of the first terminal and the second terminal according to the third embodiment. In FIGS. 23 to 25, a portion of the case 20, the portion covering the terminal stack portion 24, is indicated by a broken line. FIGS. 24 and 25 are cross-sectional views taken along alternate long and short dash lines Y1-Y1 and Y2-Y2 in FIG. 23, respectively. The terminal stack portion 24 according to the third embodiment has the same configuration as the terminal stack portions 24 according to the first embodiment, except for a first connection portion 22al and a second connection portion 23al. In the third embodiment, the same components as those of the terminal stack portions 24 according to the first embodiment are denoted by the same reference characters, and the description thereof will be simplified or omitted.

The terminal stack portion 24 includes the first terminal 22 and the second terminal 23, and the second terminal 23 is stacked on the first terminal 22. As illustrated in FIGS. 24 and 25, in the terminal stack portion 24, a portion corresponding to a first wiring portion 22a2 included in the first terminal 22 and a portion corresponding to a second wiring portion 23a2 included in the second terminal 23 are sealed and fixed in the case 20.

The first terminal 22 includes a first conductive plate 22a and a first oxide film 22b. Further, the first conductive plate 22a includes the first connection portion 22al and the first wiring portion 22a2. The first wiring portion 22a2 is similar to that according to the first embodiment. The material of the first oxide film 22b and the area coating the first wiring portion 22a2 and the coating method are the same as those according to the first embodiment.

The first connection portion 22al is integrally connected to the rear end surface (not illustrated) of the first wiring portion 22a2, the rear end surface being opposite to the front end surface 22a3, and extends in the −X direction. The thicknesses of the first connection portion 22al and the first wiring portion 22a2 may be the same and uniform. The first connection portion 22al in this case is formed at one location on the rear end surface near the first side surface 22a4. The −Y direction side portion of the first connection portion 22al may be flush with the first side surface 22a4 in plan view. The ±Y direction width of the first connection portion 22al may be 30% or more and 50% or less of the ±Y direction width of the first wiring portion 22a2.

As illustrated in FIG. 25, the first connection portion 22al extends in the −X direction and is bent in the −Z direction. The rear surface of the tip portion of the first connection portion 22al may be flush with the rear surface of the first wiring portion 22a2. The first connection portion 22al is bonded to a predetermined conductive pattern (not illustrated) of the insulated circuit substrate. The bonding may be performed with the above-described bonding member or ultrasonic bonding.

As in the first embodiment, the second terminal 23 is stacked on the first terminal 22. The second terminal 23 includes a second conductive plate 23a and a second oxide film 23b. Further, the second conductive plate 23a includes a second connection portion 23al and a second wiring portion 23a2. The second wiring portion 23a2 is similar to that according to the first embodiment. The material of the second oxide film 23b and the area coating the second wiring portion 23a2 and the coating method are the same as those according to the first embodiment.

The second connection portion 23al is integrally connected to the rear end surface (not illustrated) of the second wiring portion 23a2, the rear end surface being opposite to the front end surface 23a3, and extends in the −X direction. The thicknesses of the second connection portion 23al and the second wiring portion 23a2 may be the same and uniform. The second connection portion 23al is formed at one location on the rear end surface near the second side surface 23a5. As illustrated in FIG. 23, the ±Y direction side portion of the second connection portion 23al may be flush with the second side surface 23a5 in plan view. The ±Y direction width of the second connection portion 23al may be 30% or more and 50% or less of the ±Y direction width of the first wiring portion 22a2. Therefore, when the second terminal 23 is stacked on the first terminal 22, the second connection portion 23al does not overlap the first connection portion 22al (see FIG. 23).

As illustrated in FIG. 25, the second connection portion 23al extends in the −X direction and is bent in the −Z direction. The rear surface of the tip portion of the second connection portion 23al may be flush with the rear surface of the first wiring portion 22a2 and the rear surface of the first connection portion 22a1. The second connection portion 23al is bonded to a predetermined conductive pattern (not illustrated) of the insulated circuit substrate. The bonding may be performed with be the above-described bonding member or ultrasonic bonding. Also in the semiconductor module 2 according to the third embodiment, as described above, the first oxide film 22b and the second oxide film 23b are used as the insulating members between the first wiring portion 22a2 of the first conductive plate 22a and the second wiring portion 23a2 of the second conductive plate 23a. As a result, the same effect as that according to the first embodiment is obtained. When external terminals are bonded to the first terminal 22 and the second terminal 23 of the terminal stack portion 24 of the semiconductor module 2, the external terminals are disposed in the first bonding area 22a8 of the first terminal 22 and the second bonding area 23a8 of the second terminal 23, as in the second embodiment, and laser irradiation is performed as in the second embodiment. In this way, the external terminals are bonded to the first terminal 22 and the second terminal 23.

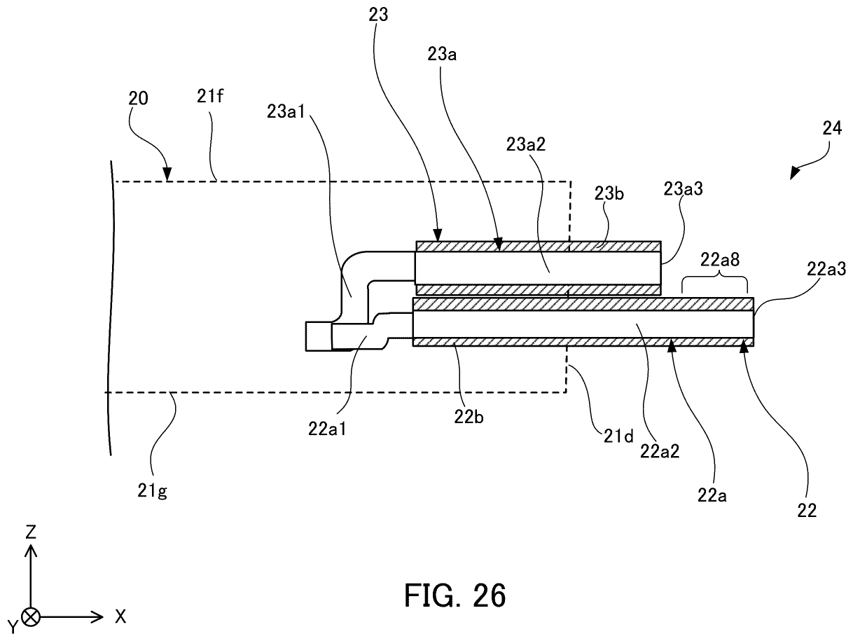

Next, modification 3-1 of the third embodiment will be described. A clad material is used for a first terminal 22 and a second terminal 23 included in a terminal stack portion 24 according to modification 3-1 as in modification 1-1. In a semiconductor module 2 according to modification 3-1, the terminal stack portion 24 has the same configuration as that according to the first embodiment. The terminal stack portion 24 in this case will be described with reference to FIG. 26. FIG. 26 is a cross-sectional view of the first terminal and the second terminal according to modification 3-1 of the third embodiment. FIG. 26 corresponds to FIG. 25.

The terminal stack portion 24 includes the first terminal 22 and the second terminal 23, and the second terminal 23 is stacked on the first terminal 22. As illustrated in FIG. 26, in the terminal stack portion 24, a portion corresponding to a first wiring portion 22a2 included in the first terminal 22 and a portion corresponding to a second wiring portion 23a2 included in the second terminal 23 are sealed and fixed in a case 20.

The first terminal 22 includes a first conductive plate 22a and a first oxide film 22b as in the case of FIG. 25 according to the third embodiment. The first terminal 22 is obtained from a clad material 22c as in modification 1-1. Therefore, the first oxide film 22b is formed only on a first front surface 22a6 and a first rear surface 22a7 of the first wiring portion 22a2 of the first conductive plate 22a. The first oxide film 22b is not formed on a front end surface 22a3, a rear end surface (reference character omitted), and first side surfaces 22a4 and 22a5 of the first wiring portion 22a2 of the first conductive plate 22a.

The second terminal 23 also includes a second conductive plate 23a and a second oxide film 23b as in the case of FIG. 25 according to the third embodiment. The second terminal 23 is also obtained from a clad material 22c as in modification 1-1. Therefore, the second oxide film 23b is formed only on a second front surface 23a6 and a second rear surface 23a7 of the second wiring portion 23a2 of the second conductive plate 23a. The second oxide film 23b is not formed on a front end surface 23a3, a rear end surface (reference character omitted), and second side surfaces 23a4 and 23a5 of the second wiring portion 23a2 of the second conductive plate 23a.

As described above, the first oxide film 22b is not formed on the front end surface 22a3, the first side surfaces 22a4 and 22a5, and the rear end surface of the first conductive plate 22a of the first terminal 22. In addition, the second oxide film 23b is not formed on the front end surface 23a3, the second side surfaces 23a4 and 23a5, and the rear end surface of the second conductive plate 23a of the second terminal 23. Therefore, in order to maintain the insulation between the first terminal 22 and the second terminal 23 according to modification 3-1, it is desirable that the creepage distance between the front end surfaces 22a3 and 23a3, the creepage distance between the first side surfaces 22a4 and 22a5 and the second side surfaces 23a4 and 23a5, and the creepage distance between the rear end surfaces be set to be longer than those in the case of FIG. 7 according to the first embodiment. For example, the front end surface 22a3 of the first terminal 22 may be formed to extend more in the ±X direction from the front end surface 23a3 of the second terminal 23, as compared with the case in FIG. 7 according to the first embodiment. Further, the first side surfaces 22a4 and 22a5 may be formed to extend more in the ±Y directions from the second side surfaces 23a4 and 23a5, respectively, as compared with the case according to the first embodiment.

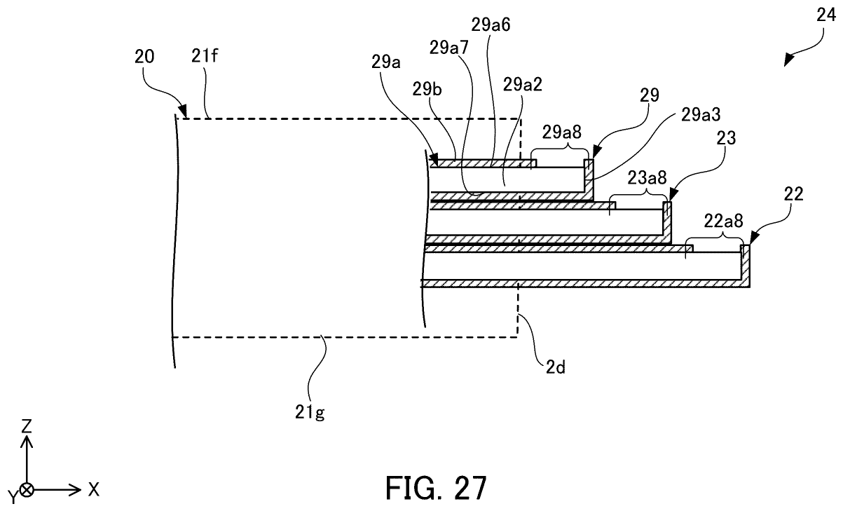

Next, modification 3-2 of the third embodiment will be described. A terminal stack portion 24 according to modification 3-2 is a case where the terminal stack portion 24 illustrated in FIGS. 23 to 25 includes another layer. That is, the present terminal stack portion 24 includes three layers. The terminal stack portion 24 in this case will be described with reference to FIG. 27. FIG. 27 is a cross-sectional view of a first terminal, a second terminal, and a third terminal according to modification 3-2 of the third embodiment. FIG. 27 illustrates the terminal stack portion 24 according to modification 3-2 and corresponds to the cross-sectional views in FIGS. 24 and 25.

The terminal stack portion 24 according to this modification 3-2 includes three-phase output terminals (a U terminal, a V terminal, and a W terminal). As illustrated in FIG. 27, the terminal stack portion 24 further includes a third terminal 29 on the second terminal 23 of the terminal stack portion 24 illustrated in FIGS. 24 and 25. The third terminal 29 included in the terminal stack portion 24 functions as a U terminal, the second terminal 23 functions as a V terminal, and the first terminal 22 functions as a W terminal. The first connection portion 22al of the first terminal 22 and the second connection portion 23al of the second terminal 23 are not illustrated.

The third terminal 29 is disposed so as to be displaced from the second terminal 23 in the −X direction, such that the area corresponding to the second bonding area 23a8 of the second terminal 23 is exposed to the outside. The third terminal 29 also includes a third conductive plate 29a and a third oxide film 29b. Further, the third conductive plate 29a includes a third connection portion (not illustrated) and a third wiring portion 29a2.

The third wiring portion 29a2 has the same material and shape as the first wiring portion 22a2 and the second wiring portion 23a2 according to the first embodiment. The ±Y direction width of the third wiring portion 29a2 is equal to the ±Y direction width of the first wiring portion 22a2 of the first terminal 22 and the second wiring portion 23a2 of the second terminal 23. The material of the third oxide film 29b and the area coating the third wiring portion 29a2 and the coating method are the same as those of the first oxide film 22b and the second oxide film 23b according to the first embodiment.

The third connection portion is integrally connected to a rear end surface (not illustrated) of the third wiring portion 29a2, the rear end surface being opposite to the front end surface 29a3, and extends in the −X direction. The thicknesses of the third connection portion and the third wiring portion 29a2 may be the same and uniform. The third connection portion may be formed with the third wiring portion 29a2 so as not to overlap the first connection portion 22al of the first terminal 22 and the second connection portion 23al of the second terminal 23 in plan view.

In addition, the third connection portion extends in the −X direction and is bent in the −Z direction in a side view (when viewed in the ±Y directions). The rear surface of the tip portion of the third connection portion may be flush with the rear surface of the first wiring portion 22a2 and the rear surface of the first connection portion 22al. The third connection portion is bonded to a predetermined conductive pattern of an insulated circuit substrate (not illustrated) together with the first connection portion 22al and the second connection portion 23a1. The bonding may be performed by the above-described bonding member or ultrasonic bonding.

As illustrated in FIG. 27, in the terminal stack portion 24 according to modification 3-2 having this configuration, a portion corresponding to the first wiring portion 22a2 included in the first terminal 22, a portion corresponding to the second wiring portion 23a2 included in the second terminal 23, and a portion corresponding to the third wiring portion 29a2 included in the third terminal 29 are sealed and fixed in the case 20.

Also in a semiconductor module 2 according to the modification 3-2 of the third embodiment, as described above, the first oxide film 22b, the second oxide film 23b, and the third oxide film 29b are used as the insulating members among the first wiring portion 22a2 of the first conductive plate 22a, the second wiring portion 23a2 of the second conductive plate 23a, and the third wiring portion 29a2 of the third conductive plate 29a. As a result, the same effect as that according to the first embodiment is obtained.

When external terminals are bonded to the first terminal 22, the second terminal 23, and the third terminal 29 of the terminal stack portion 24 of the semiconductor module 2, the external terminals are disposed in the first bonding area 22a8 of the first terminal 22, the second bonding area 23a8 of the second terminal 23, and a third bonding area 29a8 of the third terminal 29, as in the second embodiment, and laser irradiation is performed as in the second embodiment. In this way, the external terminals are bonded to the first terminal 22, the second terminal 23, and the third terminal 29.

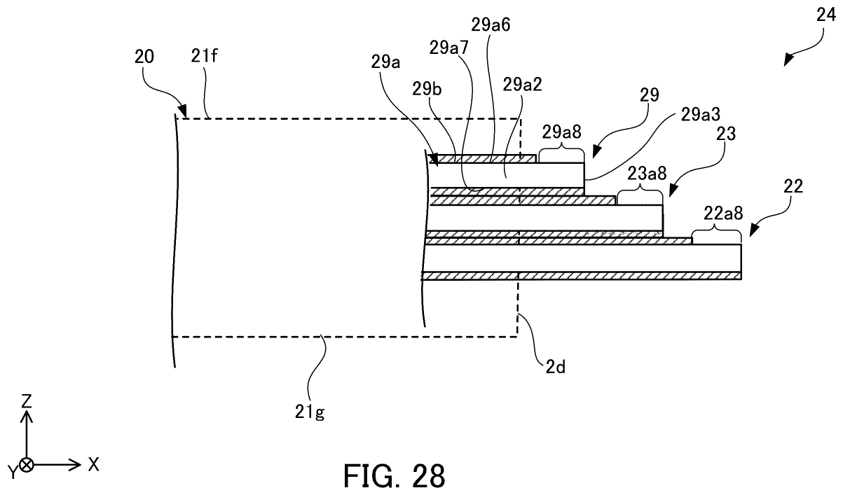

Next, modification 3-3 of the third embodiment will be described. As in modification 1-1, a clad material is used for the first terminal 22, the second terminal 23, and the third terminal 29 included in the terminal stack portion 24 according to modification 3-2. In a semiconductor module 2 according to modification 3-3, a terminal stack portion 24 has the same configuration as that according to modification 3-2. The terminal stack portion 24 in this case will be described with reference to FIG. 28. FIG. 28 is a cross-sectional view of a first terminal, a second terminal, and a third terminal according to modification 3-3 of the third embodiment. FIG. 28 corresponds to FIG. 27.

The terminal stack portion 24 includes a first terminal 22, a second terminal 23, and a third terminal 29. The second terminal 23 is stacked on the first terminal 22, and the third terminal 29 is stacked on the second terminal 23. As illustrated in FIG. 28, in the case of this terminal stack portion 24, a portion corresponding to a first wiring portion 22a2 included in the first terminal 22, a portion corresponding to a second wiring portion 23a2 included in the second terminal 23, and a portion corresponding to a third wiring portion 29a2 included in the third terminal 29 are sealed and fixed in a case 20.

The first terminal 22 and the second terminal 23 are the same as those according to modification 3-1 illustrated in FIG. 26. The third terminal 29 includes a third conductive plate 29a and a third oxide film 29b, as in the case of FIG. 27 according to modification 3-2. The third terminal 29 is obtained from a clad material 22c, as in modification 1-1. Therefore, the third oxide film 29b is formed only on a third front surface 29a6 and a third rear surface 29a7 of the third wiring portion 29a2 of the third conductive plate 29a. The third oxide film 29b is not formed on a front end surface 29a3, a rear end surface (reference character omitted), and third side surfaces (not illustrated) of the third wiring portion 29a2 of the third conductive plate 29a. The third side surfaces correspond to the first side surfaces 22a4 and 22a5 of the first conductive plate 22a.

Also in modification 3-3, it is desirable that the creepage distance between the front end surfaces 22a3 and 23a3, the creepage distance between the first side surfaces 22a4 and 22a5 and the second side surfaces 23a4 and 23a5, and the creepage distance between the rear end surfaces be set to be longer than those in the case of FIG. 7 according to the first embodiment in order to maintain the insulation between the first terminal 22 and the second terminal 23, as in modification 3-1.

In addition, the second oxide film 23b and the third oxide film 29b are not formed on the front end surfaces 23a3 and 29a3, the second side surfaces 23a4 and 23a5, the third side surfaces, and the rear end surfaces of the second conductive plate 23a and the third conductive plate 29a of the second terminal 23 and the third terminal 29. Therefore, in order to maintain the insulation between the second terminal 23 and the third terminal 29 according to modification 3-3, it is desirable that the creepage distance between the front end surfaces 23a3 and 29a3, the creepage distance between the second side surfaces 23a4 and 23a5 and the third side surfaces, and the creepage distance between the rear end surfaces be set to be longer than those in the case of FIG. 27 of modification 3-2. For example, the front end surface 23a3 of the second terminal 23 may be formed to extend more in the ±X direction from the front end surface 29a3 of the third terminal 29 as compared with the case in FIG. 27 according to modification 3-2. In addition, the second side surfaces 23a4 and 23a5 may be formed to extend more in the ±Y directions from the third side surfaces, as compared with the case according to modification 3-2.

FIG. 28 illustrates a case where a first bonding area 22a8 of the first terminal 22, a second bonding area 23a8 of the second terminal 23, and a third bonding area 29a8 of the third terminal 29 of the terminal stack portion 24 of the semiconductor module 2 are open, as in FIG. 27.

The first oxide film 22b and the second oxide film 23b corresponding to the first bonding area 22a8 and the second bonding area 23a8 of the first terminal 22 and the second terminal 23 are removed by laser irradiation, as in modification 1-1. Similarly, the third oxide film 29b corresponding to the third bonding area 29a8 of the third terminal 29 is removed by laser irradiation. For example, an area of the third oxide film 29b of the third terminal 29 of the third terminal 29 may be removed by laser irradiation. For example, an area having a predetermined length in the −X direction from the front end surface 29a3 in plan view and extending from one third side surface to the other third side surface in plan view may be removed by laser irradiation. In addition, also in modification 3-3, in order to remove the first oxide film 22b, the second oxide film 23b, and the third oxide film 29b, polishing with a file or cutting with a milling cutter may be used, other than laser irradiation, as in the first embodiment.

### Fourth Embodiment

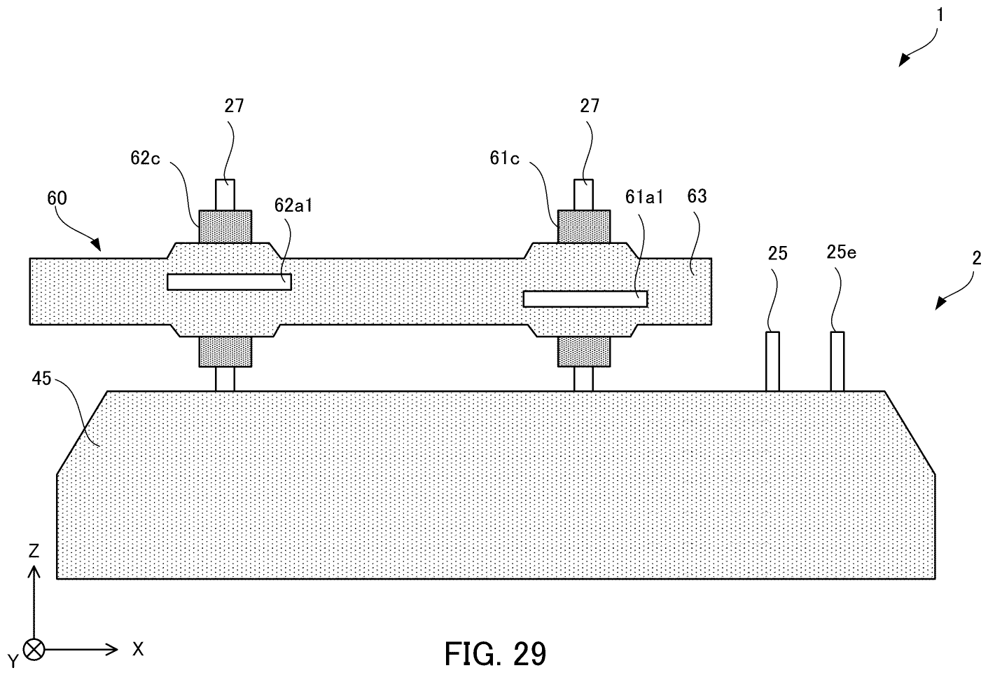

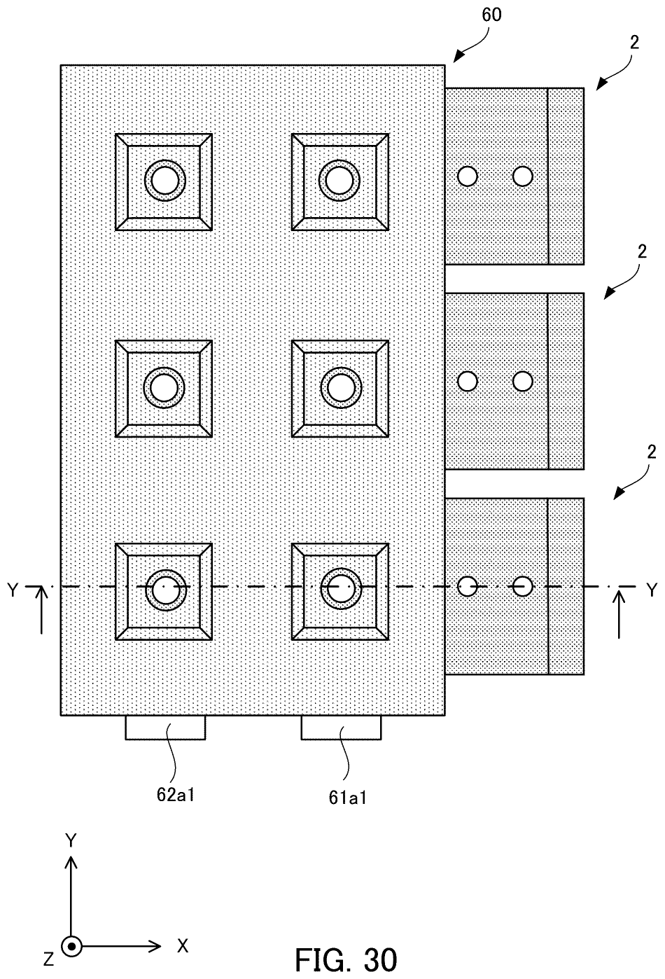

A semiconductor device according to a fourth embodiment will be described with reference to FIGS. 29 and 30. FIG. 29 is a side view of the semiconductor device according to the fourth embodiment, and FIG. 30 is a plan view of the semiconductor device according to the fourth embodiment. FIG. 29 is a side view of the semiconductor device 1 in FIG. 30 viewed in the +Y direction.

As illustrated in FIG. 29, the semiconductor device 1 includes semiconductor modules 2 and a bus bar 60. The individual semiconductor module 2 includes external connection terminals 27, a control terminal 25, a sense terminal 25e, and a main body portion 45. The external connection terminals 27, the control terminal 25, and the sense terminal 25e are disposed perpendicularly to the front surface of the main body portion 45. The external connection terminals 27, the control terminal 25, and the sense terminal 25e are electrically connected to semiconductor chips inside the main body portion 45. The details of the semiconductor module 2 will be described later. As illustrated in FIG. 30, three semiconductor modules 2, each of which includes the above-described components, are arranged with their long sides parallel to each other.

In the bus bar 60, a P-type conductive plate and an N-type conductive plate are sealed by a sealing portion 63. The P-type conductive plate include first main terminal connection portions 61c, and the N-type conductive plate includes second main terminal connection portions 62c. A first external connection portion 61al and a second external connection portion 62al extend from a side portion of the sealing portion 63 to the outside of the sealing portion 63. The bus bar 60 is disposed on the three arranged semiconductor modules 2. The external connection terminals 27 of the semiconductor modules 2 are inserted through the bus bars 60. Each of the external connection terminals 27 is directly connected to the N-type conductive plate and the P-type conductive plate in the bus bar 60. Details of the bus bar 60 will be described later.

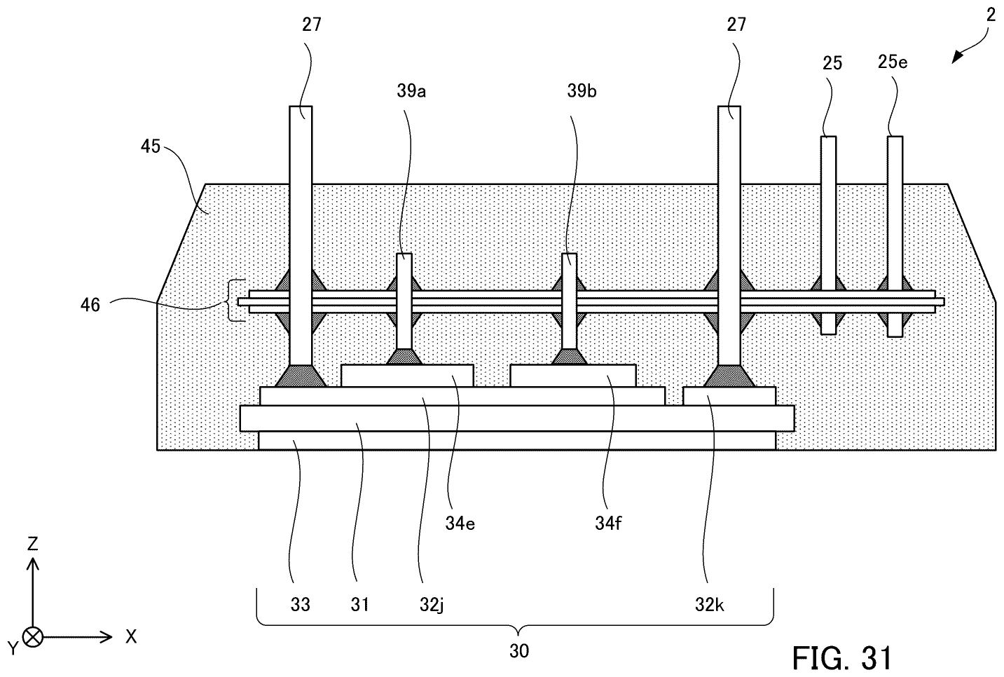

Next, the individual semiconductor module 2 will be described with reference to FIG. 31. FIG. 31 is a cross-sectional view of a semiconductor module according to the fourth embodiment. FIG. 31 is a cross-sectional view taken along an alternate long and short dash line Y-Y in FIG. 30.

As illustrated in FIG. 31, the semiconductor module 2 includes an insulated circuit substrate 30, semiconductor chips 34e and 34f, a printed circuit board 46, external connection terminals 27, a control terminal 25, a sense terminal 25e, and conductive posts 39a and 39b. In the semiconductor module 2, these components are sealed by a main body portion 45. The semiconductor module 2 is sealed by the main body portion 45 such that the rear surface of the insulated circuit substrate 30 is exposed. The semiconductor module 2 is formed by the main body portion 45 so as to have a substantially cuboid shape (a rectangular shape in plan view). However, the upper surface side of the individual short side is processed into a tapered shape.

The insulated circuit substrate 30 includes an insulating plate 31, a metal plate 33 provided on the rear surface of the insulating plate 31, and wiring plates 32j and 32k provided on the front surface of the insulating plate 31. The insulating plate 31 and the metal plate 33 have a rectangular shape in plan view. The insulating plate 31 and the metal plate 33 may have rounded or chamfered corner portions. In plan view, the area of the metal plate 33 is smaller than the area of the insulating plate 31, and the metal plate 33 is formed inside the insulating plate 31.

The insulating plate 31, the metal plate 33, and the wiring plates 32j and 32k are made of the same materials as those of the insulating plate 31, the metal plate 33, and the wiring plates 32a to 32h according to the first embodiment. The wiring plates 32i and 32k may include a wiring plate capable of realizing a function needed in the semiconductor module 2 according to the fourth embodiment.

The semiconductor chip 34e includes a switching element. The switching element is, for example, an IGBT or a power MOSFET. When the semiconductor chip 34e is an IGBT, an input electrode (a collector electrode) is provided as a main electrode on the rear surface, and a control electrode (a gate electrode) and an output electrode (an emitter electrode) as a main electrode are provided on the front surface. When the semiconductor chip 34e is a power MOSFET, the semiconductor chip 34e includes an input electrode (a drain electrode) as a main electrode on the rear surface, and includes a control electrode (a gate electrode) and an output electrode (a source electrode) as a main electrode on the front surface. The rear surface of the semiconductor chip 34e is bonded to the wiring plate 32j by a bonding member (not illustrated). The conductive post 39a is electrically and mechanically connected to the main electrode on the front surface of the semiconductor chip 34e by a bonding member. Similarly, a conductive post (not illustrated) is connected to the control electrode on the front surface of the semiconductor chip 34e.

The semiconductor chip 34f includes a diode element. The diode element is, for example, an FWD such as a Schottky barrier diode (SBD) or a P-intrinsic-N (PIN) diode. The semiconductor chip 34f includes an output electrode (a cathode electrode) as a main electrode on the rear surface and an input electrode (an anode electrode) as a main electrode on the front surface. The rear surface of the semiconductor chip 34f is bonded to the wiring plate 32j by a bonding member (not illustrated). The conductive post 39b is also electrically and mechanically connected to the main electrode on the front surface of the semiconductor chip 34f by a bonding member as appropriate.

The printed circuit board 46 is provided so as to face the insulated circuit substrate 30 disposed horizontally. The printed circuit board 46 includes an insulating plate and a plurality of upper circuit patterns formed on the front surface of the insulating plate. The printed circuit board 46 includes a plurality of lower circuit patterns on the rear surface of the insulating plate. Further, a plurality of through holes penetrating from the front surface to the rear surface of the printed circuit board 46 are formed in predetermined positions of the printed circuit board 46. The external connection terminals 27 and the conductive posts 39a and 39b are electrically connected to the upper circuit patterns and the lower circuit patterns of the printed circuit board 46 as appropriate. The control terminal 25 and the sense terminal 25e are electrically connected to the printed circuit board 46. The control terminal 25 is electrically connected to the conductive posts 39a and 39b through the upper circuit patterns and the lower circuit patterns. The sense terminal 25e is electrically connected to the emitter electrode of the semiconductor chip 34e and the anode electrode of the semiconductor chip 34f through the upper circuit patterns and the lower circuit patterns.

The external connection terminals 27 are press-fitted and inserted into the through holes of the printed circuit board 46. In this case, the press-fitted portions are covered with solder. The external connection terminals 27 are electrically connected to the upper circuit patterns and the lower circuit patterns of the printed circuit board 46. One end portion of each of the external connection terminals 27 is bonded to a corresponding one of the wiring plates 32j and 32k of the insulated circuit substrate 30 via solder. The external connection terminals 27 have a columnar shape, and have a circular or rectangular cross section. The external connection terminals 27 are mainly made of a material having excellent electric conductivity. Examples of the material include silver, copper, nickel, and an alloy containing at least one of these metals. The surface of the individual external connection terminal 27 may be plated to improve corrosion resistance. Examples of the material for the plating include nickel, a nickel-phosphorus alloy, and a nickel-boron alloy.

The control terminal 25 and the sense terminal 25e are press-fitted and inserted into through holes of the printed circuit board 46. In this case, the press-fitted portions are covered with solder. The control terminal 25 and the sense terminal 25e are electrically connected to the upper circuit patterns and the lower circuit patterns of the printed circuit board 46. The control terminal 25 and the sense terminal 25e have a pin shape, and have a circular or rectangular cross section. The lengths of the control terminal 25 and the sense terminals 25e are sufficiently longer than the lengths of the conductive posts 39a and 39b. The control terminal 25a and the sense terminal 25e are mainly made of a material having excellent electric conductivity. Examples of the material include silver, copper, nickel, and an alloy containing at least one of these metals. The surfaces of the control terminal 25 and the sense terminal 25e may be plated to improve corrosion resistance. Examples of the material for the plating include nickel, a nickel-phosphorus alloy, and a nickel-boron alloy.

The conductive posts 39a and 39b are press-fitted and inserted into through holes of the printed circuit board 46. In this case, the press-fitted portions are covered with solder. The conductive posts 39a and 39b are electrically connected to the upper circuit patterns and the lower circuit patterns of the printed circuit board 46. One end portion of each of the conductive posts 39a and 39b is bonded to a corresponding one of the main electrodes and the control electrodes of the semiconductor chips 34e and 34f via solder. The conductive posts 39a and 39b have a columnar shape and have a circular or rectangular cross section. The lengths of the conductive posts 39a and 39b are sufficiently shorter than the length of the external connection terminals 27. The conductive posts 39a and 39b are mainly made of a material having excellent electric conductivity. Examples of the material include silver, copper, nickel, and an alloy containing at least one of these metals. The surfaces of the conductive posts 39a and 39b may be plated to improve corrosion resistance. Examples of the material for the plating include nickel, a nickel-phosphorus alloy, and a nickel-boron alloy. The bonding member for bonding the conductive posts 39a and 39b is solder or a metal sintered body. As the solder, lead-free solder is used. The lead-free solder contains, for example, an alloy containing at least two of tin, silver, copper, zinc, antimony, indium, and bismuth as a main component. The solder may contain an additive. The additive is, for example, nickel, germanium, cobalt, or silicon. When the solder contains an additive, wettability, gloss, and bonding strength are improved, and reliability is consequently improved. The metal used in the metal sintered body is, for example, silver or a silver alloy.

The lower end portions of the external connection terminals 27, the control terminal 25, and the sense terminal 25e are sealed by the main body portion 45. The external connection terminals 27, the control terminal 25, and the sense terminal 25e are arranged on a straight line passing through the center of the front surface along the longitudinal direction on the front surface of the semiconductor module 2 in plan view. The conductive posts 39a and 39b are sealed by the main body portion 45.

The main body portion 45 is formed using a sealing member. The sealing member contains a thermosetting resin such as an epoxy resin, a phenol resin, or a maleimide resin, and a filler contained in the thermosetting resin. An example of the sealing member of the main body portion 45 is an epoxy resin containing a filler. As the filler, an inorganic filler is used. Examples of the inorganic filler include silicon oxide, aluminum oxide, boron nitride, and aluminum nitride. Further, the sealing member contains a release agent in an amount as needed. As the release agent, for example, a wax-based release agent, a silicone-based release agent, or a fluorine-based release agent is used. In the semiconductor module 2 sealed by the main body portion 45, the metal plate 33 of the insulated circuit substrate 30 is exposed to the outside on the rear surface. In this case, the metal plate 33 may be flush with the rear surface of the main body portion 45 or may protrude from the rear surface to the outside.

A cooling module (not illustrated) may be attached to the rear surface of the semiconductor module 2 via solder, silver solder, or the like. In this case, mounting holes (not illustrated) of the semiconductor module 2 and the cooling module are attached to each other with screws. Thus, the heat dissipation of the semiconductor module 2 is improved. The cooling module in this case is made of, for example, a metal having excellent thermal conductivity. The metal is, for example, aluminum, iron, silver, copper, or an alloy containing at least one of these metals. As the cooling module, a heatsink including one or more fins, a cooling device by water cooling, or the like may be used. The surface of the cooling module may also be plated to improve corrosion resistance. In this case, the plating material used is, for example, nickel, a nickel-phosphorus alloy, or a nickel-boron alloy.

The semiconductor module 2 merely includes the main body portion 45 in which the insulated circuit substrate 30, the semiconductor chips 34e and 34f, the printed circuit board 46, and the like are sealed with a sealing member. In the case of the semiconductor module 2, for example, the insulated circuit substrate 30, the semiconductor chips 34e and 34f, the printed circuit board 46, and the like may be stored in a case, and the inside of the case may be sealed with a sealing member, such that the external connection terminals 27, the control terminal 25, the sense terminal 25e, and the conductive posts 39a and 39b extend upward.

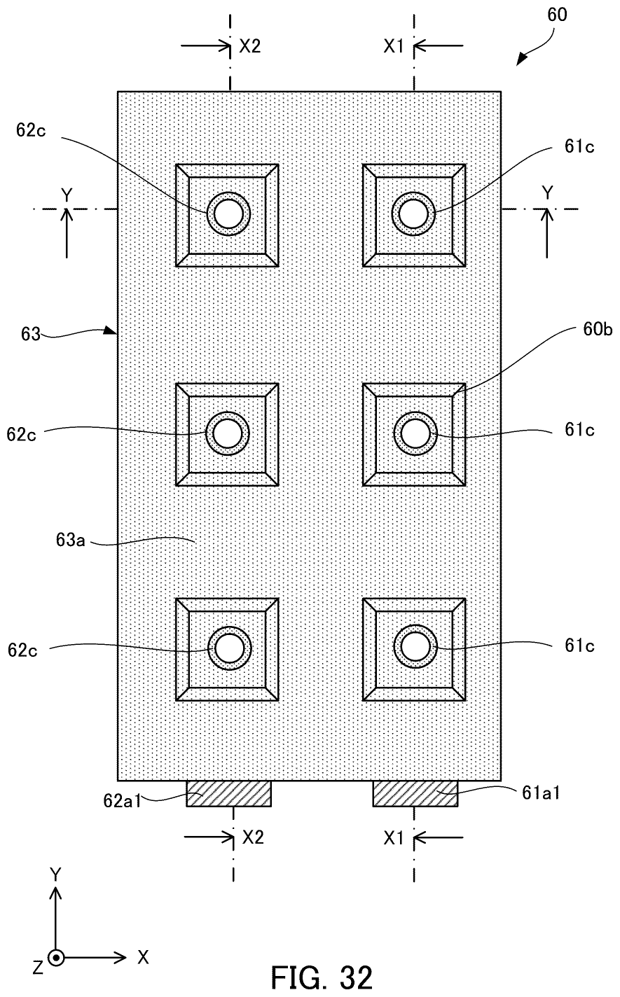

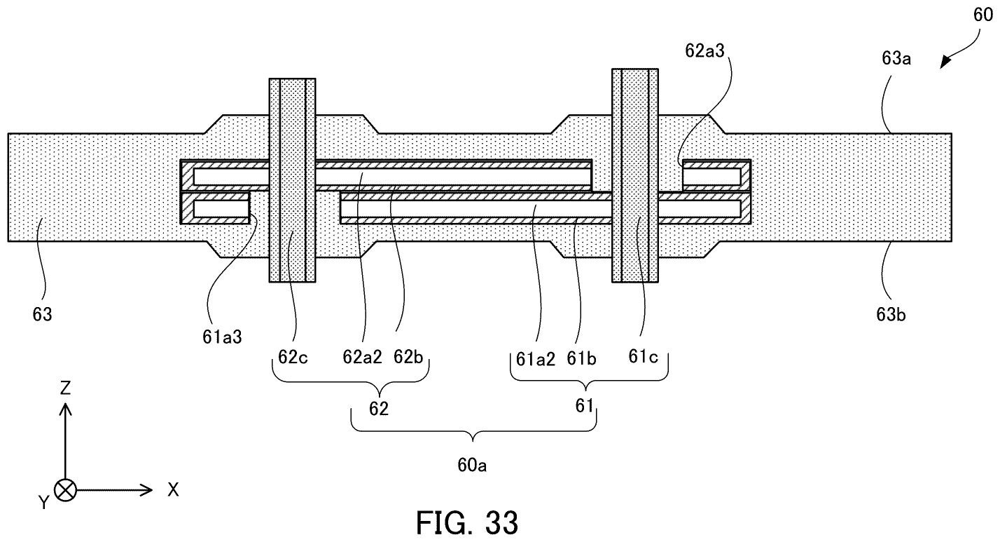

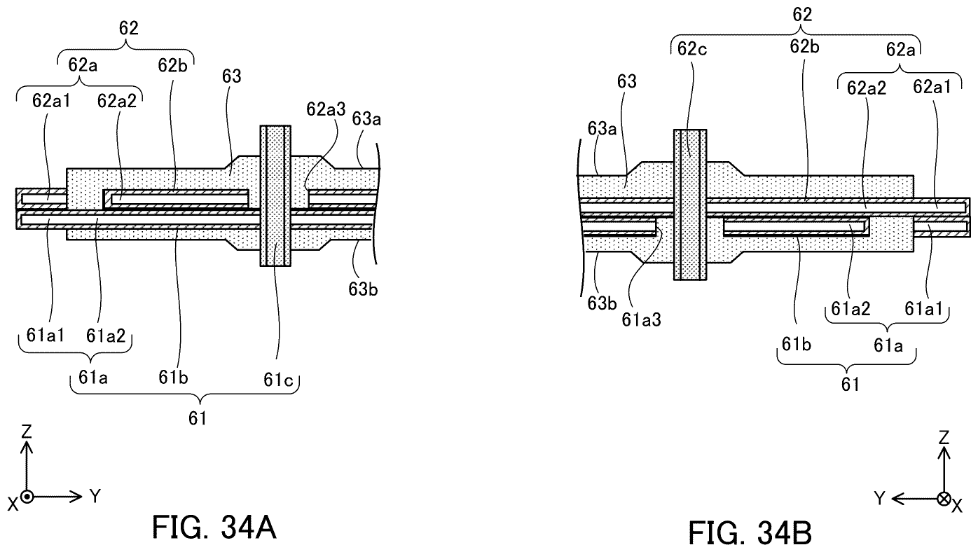

Next, the bus bar 60 will be described with reference to FIGS. 32 to 34B. FIG. 32 is a plan view of the bus bar according to the fourth embodiment, FIG. 33 is a first cross-sectional view of the bus bar according to the fourth embodiment, and FIGS. 34A and 34B are second cross-sectional views of the bus bar according to the fourth embodiment. FIG. 33 is a cross-sectional view taken along a dashed-dotted line Y-Y in FIG. 32. FIGS. 34A and 34B are cross-sectional views taken along dashed-dotted lines X1-X1 and X2-X2 in FIG. 32, respectively.

As illustrated in FIG. 33, the bus bar 60 includes the sealing portion 63 that seals a stacked body 60a. The stacked body 60a is formed by stacking a P-type conductive portion 61 and an N-type conductive portion 62 in order from the bottom.

The bus bar 60 includes first main terminal connection portions 61c and second main terminal connection portions 62c that penetrate a front surface 63a and a rear surface 63b of the sealing portion 63. The first main terminal connecting portions 61c and the second main terminal connection portions 62c are arranged along the longitudinal direction of the sealing portion 63 (in two rows in total, see FIG. 32).

Each of the P-type conductive portion 61 and the N-type conductive portion 62 has a sheet shape (a flat plate shape). The P-type conductive portion 61 includes a first conductive plate 61a, a first oxide film 61b, and the first main terminal connection portions 61c. The first conductive plate 61a integrally includes the first external connection portion 61al and a first wiring portion 61a2. The thickness of the first conductive plate 61a is approximately uniform as a whole. That is, the first external connection portion 61al and the first wiring portion 61a2 also have approximately the same thickness. The first conductive plate 61a is mainly made of a material having excellent electric conductivity. Examples of the material include copper and a copper alloy.

The first wiring portion 61a2 has a rectangular flat plate shape in plan view. The first wiring portion 61a2 includes a front surface, a rear surface, and four side surfaces. The front surface and the rear surface have a rectangular shape in plan view and have the same size. The first wiring portion 61a2 includes at least an area in which all of the first main terminal connection portions 61c and the second main terminal connection portions 62c illustrated in FIG. 32 are disposed.

The first main terminal connection portions 61c are attached to the first wiring portion 61a2, and the first wiring portion 61a2 is electrically connected to the first main terminal connection portions 61c. The first wiring portion 61a2 has first through holes 61a3 through which the second main terminal connection portions 62c pass without contact. Three first through holes 61a3 are provided along the −X direction side of the first wiring portion 61a2 in plan view.

The four side surfaces of the first wiring portion 61a2 are provided to sequentially surround the four sides of the front surface and the rear surface. These side surfaces correspond to a pair of long sides (parallel to the longitudinal direction) and a pair of short sides (parallel to the lateral direction) of the sealing portion 63 illustrated in FIG. 32 in plan view. The first external connection portion 61al is bonded to the −Y direction side surface (parallel to the lateral direction) among the four side surfaces. The first external connection portion 61al extends perpendicularly (in the −Y direction) to this side surface.

The first external connection portion 61al has a rectangular flat plate shape in plan view. The ±X direction width of the first external connection portion 61al is smaller than the ±X direction width of the first wiring portion 61a2. The −Y direction side surface of the first external connection portion 61al is the −Y direction endmost portion of the P-type conductive portion 61. The +Y direction side surface of the first external connection portion 61al is integrally bonded to the −Y direction side surface of the first wiring portion 61a2.

The first oxide film 61b is provided on the surface of the first conductive plate 61a. The first oxide film 61b is provided on each of the front surface and the rear surface of the first wiring portion 61a2 and the side surfaces sequentially surrounding the front surface and the rear surface. The first oxide film 61b is provided on each of the front surface and the rear surface of the first external connection portion 61al and the side surfaces sequentially surrounding the front surface and the rear surface. The first oxide film 61b is not provided inside the individual first through hole 61a3 of the first wiring portion 61a2. The first oxide film 61b is provided at least on the surface of the first wiring portion 61a2 of the first conductive plate 61a.

The individual first main terminal connection portion 61c has a tubular shape and includes an insertion hole into which an external connection terminal 27 is inserted. The individual first main terminal connection portion 61c is made of a metal having excellent electric conductivity. Examples of the metal include copper, a copper alloy, aluminum, and an aluminum alloy. The diameter of the individual first main terminal connection portion 61c may be smaller than the diameter of the corresponding external connection terminal 27. In this case, the individual external connection terminal 27 may be press-fitted into the corresponding first main terminal connection portion 61c. The first main terminal connection portions 61c are electrically and mechanically attached to the first wiring portion 61a2. For example, as illustrated in FIG. 33, the individual first main terminal connection portion 61c is vertically attached to the front surface of the first wiring portion 61a2. As illustrated in FIG. 32, three first main terminal connection portions 61c are linearly attached to the first wiring portion 61a2 along the longitudinal direction. The individual first main terminal connection portion 61c penetrates the stacked body 60a and is attached to the first wiring portion 61a2.

The N-type conductive portion 62 is stacked on the P-type conductive portion 61. The N-type conductive portion 62 includes a second conductive plate 62a, a second oxide film 62b, and second main terminal connection portions 62c. The second conductive plate 62a integrally includes a second external connection portion 62al and a second wiring portion 62a2. The thickness of the second conductive plate 62a is approximately uniform as a whole. That is, the second external connection portion 62al and the second wiring portion 62a2 also have approximately the same thickness. The second conductive plate 62a is mainly made of a material having excellent electric conductivity. Examples of the material include copper and a copper alloy.

The second wiring portion 62a2 has a rectangular flat plate shape in plan view. The second wiring portion 62a2 has the same shape as the first wiring portion 61a2 in plan view. When the N-type conductive portion 62 is stacked on the P-type conductive portion 61, the second wiring portion 62a2 overlaps the first wiring portion 61a2. The second wiring portion 62a2 includes a front surface, a rear surface, and four side surfaces. The front surface and the rear surface have a rectangular shape in plan view and have the same size. The second wiring portion 62a2 includes at least an area in which all of the first main terminal connection portions 61c and the second main terminal connection portions 62c illustrated in FIG. 32 are disposed.

The second main terminal connection portion 62c is attached to the second wiring portion 62a2, and the second wiring portion 62a2 is electrically connected to the second main terminal connection portion 62c. The second wiring portion 62a2 has second through holes 62a3 through which the first main terminal connection portions 61c pass without contact. Three second through holes 62a3 are provided along the ±X direction side of the second wiring portion 62a2 in plan view.

Therefore, when the N-type conductive portion 62 is stacked on the P-type conductive portion 61, the first main terminal connection portions 61c of the P-type conductive portion 61 pass through their respective second through holes 62a3 in the second wiring portion 62a2. The second main terminal connection portions 62c of the N-type conductive portion 62 penetrate their respective first through holes 61a3 in the first wiring portion 61a2. Therefore, the first main terminal connection portions 61c and the second main terminal connection portions 62c have the same potential as the first conductive plate 61a and the second conductive plate 62a, respectively, and different potentials are maintained between the first main terminal connection portions 61c and the second main terminal connection portions 62c.

The four side surfaces of the second wiring portion 62a2 are provided to sequentially surround the four sides of the front surface and the rear surface. These side surfaces correspond to a pair of long sides (parallel to the longitudinal direction) and a pair of short sides (parallel to the lateral direction) of the sealing portion 63 illustrated in FIG. 32 in plan view. The second external connection portion 62al is bonded to the −Y direction side surface (parallel to the lateral direction) among the four side surfaces. The second external connection portion 62al extends perpendicularly (in the −Y direction) to the side surface.

The second external connection portion 62al has a rectangular flat plate shape in plan view. The second external connection portion 62al may have the same shape and size as the first external connection portion 61al. The +X direction width of the second external connection portion 62al is smaller than the ±X direction width of the second wiring portion 62a2. The −Y direction side surface of the second external connection portion 62al is the −Y direction endmost portion of the N-type conductive portion 62. The −Y direction side surface of the second external connection portion 62al is integrally bonded to the −Y direction side surface of the second wiring portion 62a2. Therefore, when the N-type conductive portion 62 is stacked on the P-type conductive portion 61, the second external connection portion 62al does not overlap the first external connection portion 61al in plan view.

The second oxide film 62b is provided on the surface of the second conductive plate 62a. The second oxide film 62b is provided on each of the front surface and the rear surface of the second wiring portion 62a2 and the side surfaces sequentially surrounding the front surface and the rear surface. The second oxide film 62b is provided on each of the front surface and the rear surface of the second external connection portion 62al and the side surfaces sequentially surrounding the front surface and the rear surface. The second oxide film 62b is not provided inside the second through holes 62a3 in the second wiring portion 62a2.

The individual second main terminal connection portion 62c has a tubular shape and includes an insertion hole into which an external connection terminal 27 is inserted. The individual second main terminal connection portion 62c is made of a metal having excellent electric conductivity. Examples of the metal include copper, a copper alloy, aluminum, and an aluminum alloy. The diameter of the individual second main terminal connection portion 62c may be smaller than the diameter of the corresponding external connection terminal 27. In this case, the individual external connection terminal 27 may be press-fitted into the corresponding second main terminal connection portion 62c. The second main terminal connection portions 62c are electrically and mechanically attached to the second wiring portion 62a2. For example, as illustrated in FIG. 33, the individual second main terminal connection portion 62c is vertically attached to the front surface of the second wiring portion 62a2. As illustrated in FIG. 32, three second main terminal connection portions 62c are linearly attached along the longitudinal direction. The individual second main terminal connection portion 62c penetrates the stacked body 60a and is attached to the second wiring portion 62a2.

The sealing portion 63 seals the stacked body 60a. The sealing portion 63 has an approximately cuboid shape. The sealing portion 63 may have rounded or chamfered corners and sides. The sealing portion 63 seals the stacked body 60a except for the first main terminal connection portions 61c and the second main terminal connection portions 62c, which are a plurality of insertion holes into which the external connection terminals 27 are respectively inserted, and the first external connection portion 61al of the P-type conductive portion 61 and the second external connection portion 62al of the N-type conductive portion 62. That is, the first main terminal connection portions 61c and the second main terminal connection portions 62c penetrate the front surface 63a and the rear surface 63b of the sealing portion 63. The sealing portion 63 seals the periphery of the individual second main terminal connection portion 62c penetrating the corresponding first through hole 61a3 in the first conductive plate 61a. The sealing portion 63 seals the periphery of the individual first main terminal connection portion 61c penetrating the corresponding second through hole 62a3 in the second conductive plate 62a.

On the front surface 63a and the rear surface 63b of the sealing portion 63, pedestal portions 60b are formed at positions where the first main terminal connection portions 61c and the second main terminal connection portions 62c penetrate. The individual pedestal portion 60b protrudes in the vertical direction from the front surface 63a and the rear surface 63b, to achieve a thickness thicker than the thickness between the front surface 63a and the rear surface 63b. The sealing portion 63 is made of a sealing member similar to that of the main body portion 45.

Also in the case of this bus bar 60, as described above, the first oxide film 61b and the second oxide film 62b are used as the insulating members between the first wiring portion 61a2 of the P-type conductive portion 61 and the second wiring portion 62a2 of the N-type conductive portion 62. As a result, the same effect as that according to the first embodiment is obtained. When external terminals are bonded to the P-type conductive portion 61 and the N-type conductive portion 62 of the stacked body 60a of the bus bar 60, the external terminals are disposed on the first external connection portion 61al of the P-type conductive portion 61 and the second external connection portion 62al of the N-type conductive portion 62 as in the second embodiment, and laser irradiation is performed as in the second embodiment. In this way, the external terminals are bonded to the P-type conductive portion 61 and the N-type conductive portion 62.

According to the disclosed technique, the insulation between conductive plates is maintained.

The following supplementary notes are additionally provided in connection with the embodiments including the first to fourth embodiments.
(Supplementary Note 1) An electronic module, comprising:
   a first conductive plate which contains copper or a copper alloy as a main component thereof;
   a second conductive plate which has a main surface that faces the first conductive plate and has a side surface that extends continuously from the main surface, and which contains copper or a copper alloy as a main component thereof; and
   an electrically insulating metal oxide layer which is provided on the main surface and the side surface of the second conductive plate and which contains a metal oxide of an element different from a metal of the second conductive plate.
(Supplementary Note 2) The electronic module according to supplementary note 1,
   wherein the first conductive plate has a main surface that faces the second conductive plate and has a side surface that extends continuously from the main surface, and
   wherein the first conductive plate includes an electrically insulating metal oxide layer that is provided on the main surface and the side surface of the first conductive plate and that contains a metal oxide of an element different from a metal of the first conductive plate.
(Supplementary Note 3) The electronic module according to supplementary note 2, further comprising:
   a third conductive plate which has a main surface that faces the second conductive plate and has a side surface that extends continuously from the main surface, and which contains copper or a copper alloy as a main component thereof; and
   an electrically insulating metal oxide layer which is provided on the main surface and the side surface of the third conductive plate, and which contains a metal oxide of an element different from a metal of the third conductive plate.
(Supplementary Note 4) The electronic module according to supplementary note 3, wherein the metal oxide layer provided on each of the main surface and the side surface of the first conductive plate, the second conductive plate, or the third conductive plate contains an aluminum oxide.
(Supplementary Note 5) The electronic module according to supplementary note 3, wherein the metal oxide layer provided on each of the main surface and the side surface of the first conductive plate, the second conductive plate, or the third conductive plate has a thickness of 20 μm or more.
(Supplementary Note 6) The electronic module according to supplementary note 1 or 2, wherein the first conductive plate has one end portion extending further outward beyond the second conductive plate, and the one end portion includes a first bonding area in which a surface of the first conductive plate is exposed.
(Supplementary Note 7) The electronic module according to supplementary note 1 or 2, further comprising:
   an electrically insulating metal oxide layer which is provided on another main surface of the second conductive plate, said another main surface being opposite to the main surface of the second conductive plate, and which contains a metal oxide of an element different from a metal of the second conductive plate; and
   a second bonding area in which a surface of the second conductive plate is exposed.
(Supplementary Note 8) The electronic module according to supplementary note 3, further comprising:
   an electrically insulating metal oxide layer which is provided on another main surface of the third conductive plate, said another main surface being opposite to the main surface of the third conductive plate, and which contains a metal oxide of an element different from a metal of the third conductive plate; and
   a third bonding area in which a surface of the third conductive plate is exposed.
(Supplementary Note 9) The electronic module according to supplementary note 1, further comprising a bus bar including:
   the first conductive plate which has a first external connection portion at an end portion thereof;
   the second conductive plate which has a second external connection portion at an end portion thereof,
      wherein the first conductive plate and second conductive plate stacked on top of each other include a plurality of insertion holes into which a plurality of external connection terminals are inserted; and
   a sealing member that seals the first conductive plate and the second conductive plate, except for the plurality of insertion holes, the first external connection portion, and the second external connection portion.
(Supplementary Note 10) An electronic module, comprising:
   a first conductive plate which contains copper or a copper alloy as a main component thereof;
   a second conductive plate which has a main surface that faces the first conductive plate and which contains copper or a copper alloy as a main component thereof; and
   an electrically insulating metal oxide layer which is provided on the main surface of the second conductive plate and which contains a metal oxide of an element different from a metal of the second conductive plate.
(Supplementary Note 11) An electronic apparatus, comprising:
   a first electronic module including
      a first conductive plate which contains copper or a copper alloy as a main component thereof,
      a second conductive plate which has a main surface that faces the first conductive plate, has a side surface that extends continuously from the main surface, and has another main surface opposite to the main surface, and which contains copper or a copper alloy as a main component thereof, and
      an electrically insulating metal oxide layer which is provided on the main surface, the side surface, and said another main surface of the second conductive plate and which contains a metal oxide of an element different from a metal of the second conductive plate; and
   a fourth conductive plate which is bonded to the second conductive plate and contains copper or a copper alloy as a main component thereof,
   wherein a bonding portion of the second conductive plate and the fourth conductive plate includes a weld mark penetrating the metal oxide layer.
(Supplementary Note 12) The electronic apparatus according to supplementary note 11,
   wherein the first conductive plate has a main surface that faces the second conductive plate, a side surface that extends continuously from the main surface, and another main surface opposite to the main surface,
   wherein the first conductive plate includes an electrically insulating metal oxide layer which is provided on the main surface, the side surface, and said another main surface of the first conductive plate, and which contains a metal oxide of an element different from a metal of the first conductive plate,
   wherein the electronic apparatus further includes a fifth conductive plate that is bonded to the first conductive plate and that contains copper or a copper alloy as a main component, and
   wherein a bonding portion of the first conductive plate and the fifth conductive plate includes a weld mark penetrating the metal oxide layer.
(Supplementary Note 13) An electronic apparatus, comprising:
   a first electronic module including
      a first conductive plate which contains copper or a copper alloy as a main component thereof,
      a second conductive plate which has a main surface that faces the first conductive plate, has a side surface that extends continuously from the main surface, and has another main surface opposite to the main surface, and which contains copper or a copper alloy as a main component thereof, and
      an electrically insulating metal oxide layer which is provided on the main surface, the side surface, and said another main surface of the second conductive plate and which contains a metal oxide of an element different from a metal of the second conductive plate; and
   a fourth conductive plate which is bonded to the second conductive plate and contains copper or a copper alloy as a main component thereof,
   wherein a bonding portion of the second conductive plate and the fourth conductive plate includes a weld mark passing through an opening portion of the metal oxide layer provided on said another main surface of the second conductive plate.
(Supplementary Note 14) The electronic apparatus according to supplementary note 13,
   wherein the first conductive plate has a main surface that faces the second conductive plate, a side surface that extends continuously from the main surface, and another main surface opposite to the main surface,
   wherein the first conductive plate includes an electrically insulating metal oxide layer which is provided on the main surface, the side surface, and said another main surface of the first conductive plate, and which contains a metal oxide of an element different from a metal of the first conductive plate,
   wherein the electronic apparatus further includes a fifth conductive plate that is bonded to the first conductive plate and that contains copper or a copper alloy as a main component, and
   wherein a bonding portion of the first conductive plate and the fifth conductive plate includes a weld mark passing through an opening portion of the metal oxide layer provided on the main surface of the first conductive plate.
(Supplementary Note 15) The electronic apparatus according to any one of supplementary notes 11 to 14, wherein the weld mark is a laser weld mark.
(Supplementary Note 16) An electronic apparatus, comprising:
   a second electronic module including
      a first conductive plate which contains copper or a copper alloy as a main component thereof,
      a second conductive plate which has a main surface that faces the first conductive plate and another main surface opposite to the main surface, and which contains copper or a copper alloy as a main component thereof, and
      an electrically insulating metal oxide layer which is provided on the main surface and said another main surface of the second conductive plate and which contains a metal oxide of an element different from a metal of the second conductive plate; and
   a fourth conductive plate which is bonded to the second conductive plate and contains copper or a copper alloy as a main component thereof,
   wherein a bonding portion of the second conductive plate and the fourth conductive plate includes a weld mark penetrating the metal oxide layer.
(Supplementary Note 17) An electronic apparatus, comprising:
   a second electronic module including
      a first conductive plate which contains copper or a copper alloy as a main component thereof,
      a second conductive plate which has a main surface that faces the first conductive plate and another main surface opposite to the main surface, and which contains copper or a copper alloy as a main component thereof, and
      an electrically insulating metal oxide layer which is provided on the main surface and said another main surface of the second conductive plate and which contains a metal oxide of an element different from a metal of the second conductive plate; and
   a fourth conductive plate which is bonded to the second conductive plate and contains copper or a copper alloy as a main component thereof,
   wherein a bonding portion of the second conductive plate and the fourth conductive plate includes a weld mark passing through an opening portion of the metal oxide layer provided on said another main surface of the second conductive plate.
(Supplementary Note 18) An electronic module manufacturing method, comprising:
   preparing a first conductive plate that contains copper or a copper alloy as a main component thereof, and a second conductive plate which has a main surface that faces the first conductive plate and has a side surface that extends continuously from the main surface, and which contains copper or a copper alloy as a main component thereof;
   forming a coating layer on the main surface and the side surface of the second conductive plate, the coating layer containing an element different from a metal of the first conductive plate; and
   forming an electrically insulating metal oxide layer by oxidizing the coating layer.
(Supplementary Note 19) The electronic module manufacturing method according to supplementary note 18, wherein the forming of the metal oxide layer is performed by anodic oxidation.
(Supplementary Note 20) The electronic module manufacturing method according to supplementary note 19, wherein the element different from the metal of the second conductive plate is aluminum.
(Supplementary Note 21) An electronic module manufacturing method, comprising:
   preparing a first terminal including an electrically insulating coating layer covering a top surface and a bottom surface of a first conductive plate, the first conductive plate containing copper or a copper alloy as a main component thereof, the coating layer containing an element different from a metal of the first conductive plate;
   preparing a second terminal including an electrically insulating coating layer covering a top surface and a bottom surface of a second conductive plate, the second conductive plate containing copper or a copper alloy as a main component thereof, the coating layer containing an element different from the metal of the first conductive plate;
   stacking the first terminal and the second terminal; and
   fixing the first terminal and the second terminal with a resin case.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An electronic module, comprising:
a first conductive plate which contains copper or a first copper alloy as a main component thereof;
a second conductive plate which has a main surface that faces the first conductive plate and has a side surface that extends continuously from the main surface, and which contains copper or a second copper alloy as a main component thereof; and
a metal oxide layer which is provided on the main surface and the side surface of the second conductive plate, and which contains a metal oxide that is of a metal different from a metal of the second conductive plate and is electrically insulating.

2. The electronic module according to claim 1, wherein:
the first conductive plate has a main surface that faces the second conductive plate and has a side surface that extends continuously from the main surface thereof;
the electronic module further includes a first metal oxide layer that is provided on the main surface and the side surface of the first conductive plate, and that contains a first metal oxide that is of a metal different from a metal of the first conductive plate and is electrically insulating; and
the metal oxide layer provided on the second conductive plate is a second metal oxide layer, and the metal oxide contained therein is a second metal oxide.

3. The electronic module according to claim 2, further comprising:
a third conductive plate which has a main surface that faces the second conductive plate and has a side surface that extends continuously from the main surface thereof, and which contains copper or a third copper alloy as a main component thereof; and
a third metal oxide layer which is provided on the main surface and the side surface of the third conductive plate, and which contains a third metal oxide that is of a metal different from a metal of the third conductive plate and is electrically insulating.

4. The electronic module according to claim 3, wherein each of the first, second and third metal oxide layers contains an aluminum oxide.

5. The electronic module according to claim 3, wherein each of the first, second and third metal oxide layers has a thickness of 20 μm or more.

6. The electronic module according to claim 3, wherein:
the third conductive plate further includes another main surface opposite to the main surface thereof;
the electronic module further includes a fourth metal oxide layer, which is provided on said another main surface of the third conductive plate, and which contains a fourth metal oxide that is of a metal different from the metal of the third conductive plate; and
the third conductive plate further has a bonding area thereon, from which a portion of said another main surface thereof is exposed.

7. The electronic module according to claim 1, wherein:
the first conductive plate has one end thereof extending further outward beyond the second conductive plate; and
the first conductive plate further includes a bonding area thereon at the one end thereof, a surface of the first conductive plate being exposed from the bonding area.

8. The electronic module according to claim 1, wherein:
the second conductive plate further includes another main surface opposite to the main surface thereof;
the electronic module further includes a fifth metal oxide layer, which is provided on said another main surface of the second conductive plate, and which contains a fifth metal oxide that is of a metal different from the metal of the second conductive plate; and
the second conductive plate further includes a bonding area thereon, from which a portion of said another main surface thereof is exposed.

9. The electronic module according to claim 1, wherein:
the first conductive plate has a first external connection portion at an end portion thereof;
the second conductive plate has a second external connection portion at an end portion thereof;
the first conductive plate and the second conductive plate are stacked on top of each other, and include a plurality of insertion holes into which a plurality of external connection terminals are inserted;
the electronic module further includes a sealing member that seals the first conductive plate and the second conductive plate, except for the plurality of insertion holes, the first external connection portion, and the second external connection portion; and
the sealing member seals the first conductive plate and the second conductive plate to form a bus bar.

10. An electronic apparatus, comprising:
a first electronic module, including:
a first conductive plate which contains copper or a first copper alloy as a main component thereof,
a second conductive plate which has a main surface that faces the first conductive plate, has a side surface that extends continuously from the main surface, and has another main surface opposite to the main surface, the second conductive plate containing copper or a second copper alloy as a main component thereof, and
a metal oxide layer, which is provided on the main surface, the side surface, and the another main surface of the second conductive plate, and which contains a metal oxide that is of a metal different from a metal of the second conductive plate and is electrically insulating; and
a coupling plate which is bonded to the second conductive plate and contains copper or a third copper alloy as a main component thereof,
wherein a weld mark is formed at a bonding portion of the second conductive plate and the coupling plate, and penetrates the metal oxide layer.

11. The electronic apparatus according to claim 10,
wherein the first conductive plate has a main surface that faces the second conductive plate, a side surface that extends continuously from the main surface thereof, and another main surface opposite to the main surface thereof,
wherein the first conductive plate further includes another metal oxide layer, which is provided on the main surface, the side surface, and the another main surface of the first conductive plate, and which contains another metal oxide that is of a metal different from a metal of the first conductive plate and is electrically insulating,
wherein the electronic apparatus further includes a connection terminal that is bonded to the first conductive plate and that contains copper or another copper alloy as a main component thereof, and
wherein another weld mark is formed at a bonding portion of the first conductive plate and the connection terminal and penetrates the another metal oxide layer.

12. The electronic apparatus according to claim 10, wherein the weld mark is a laser weld mark.

13. An electronic module manufacturing method, comprising:
preparing
a first conductive plate that contains copper or a first copper alloy as a main component thereof, and
a second conductive plate which has a main surface that faces the first conductive plate and has a side surface that extends continuously from the main surface thereof, and which contains copper or a second copper alloy as a main component thereof;
forming a coating layer on the main surface and the side surface of the second conductive plate, the coating layer containing an element different from a metal of the first conductive plate; and
forming an electrically insulating metal oxide layer by oxidizing the coating layer.

14. The electronic module manufacturing method according to claim 13, wherein the forming of the electrically insulating metal oxide layer is performed by anodic oxidation.

15. The electronic module manufacturing method according to claim 14, wherein the element different from the metal of the first conductive plate is aluminum.
